(19) United States
(12) Patent Application Publication
(10) Pub. No.: US 2025/0133947 A1
(43) Pub. Date: Apr. 24, 2025

(54) Thermal Evaporation-Growth of Halide Perovskites Through Phosphonic Acid Addition

(71) Applicant: GEORGIA TECH RESEARCH CORPORATION, Atlanta, GA (US)

(72) Inventors: Juan-Pablo CORREA-BAENA, Atlanta, GA (US); Andres-Felipe CASTRO-MENDEZ, Atlanta, GA (US); Carlo Andrea Riccardo PERINI, Atlanta, GA (US)

(21) Appl. No.: 18/920,357

(22) Filed: Oct. 18, 2024

Related U.S. Application Data
(60) Provisional application No. 63/591,224, filed on Oct. 18, 2023.

(51) Int. Cl. H10K 71/13; H10K 30/50; H10K 71/16; H10K 85/50

(52) U.S. Cl. CPC H10K 71/135; H10K 71/16; H10K 85/50; H10K 30/50

(57) ABSTRACT

Described herein are improved methods for fabricating devices that include a perovskite active layer as well as devices made by these methods.

### CROSS-REFERENCE TO RELATED APPLICATIONS

This application claims benefit of priority of U.S. Provisional Application No. 63/591,224, filed Oct. 18, 2023, which is hereby incorporated by reference in its entirety.

### BACKGROUND

Despite the rapid increase in power conversion efficiency in perovskite solar cells (PSCs) in academic laboratories, the scalability of this technology remains a significant challenge for its commercialization. PSCs are primarily fabricated using solution processes that have limited control over thickness and uniformity over large substrates and that impose constraints on the choice of layer materials due to solvent orthogonality requirements. Vapor deposition has the potential to overcome these challenges. The thickness and uniformity of vapor-deposited films can be easily controlled with the use of quartz crystal microbalances (QCMs) and by tuning the distance between the source and the substrate. Likewise, the lack of solvents facilitates the deposition of multiple layers without causing damage to the rest of the device, enhancing the overall device stability. Despite these advantages, thermal evaporation of organic-inorganic hybrid materials suffers from a lack of control of the stoichiometry due to low sticking coefficients of the organic cations to QCMs and the thermal degradation of the organics, which lead to the formation of secondary phases. In this context, formamidinium iodide (FAI) has demonstrated better deposition control than the widely studied methylammonium iodide (MAI), as FAI exhibits a higher sticking coefficient to the QCMs and better thermal stability. Furthermore, the main FAI byproducts in the evaporation process, hydrogen cyanide and symtriazine, have not been shown to incorporate in the deposited materials.

Among the many metal halide perovskite (MHP) compositions, FAPbI₃ is one of the most promising candidates for solar cell applications. The α-FAPbI₃ phase (the perovskite phase with the space group Pm3̅m) has a band gap of 1.48 eV, close to the Shockley-Queisser maximum efficiency for single junction solar cells. However, combining FAPbI₃ and PbI₂ can form different polytypes of the hexagonal FAPbI₃ phase that are named with the Ramsdell notation as the 2H, 4H, and 6H. The 2H phase is also termed the δ phase and only contains face-sharing octahedra in its structure, whereas 4H and 6H, because of stacking faults, contain a mixture of both corner and face-sharing octahedra. While these hexagonal phases are often identified in the literature for FAPI₃, PbI₂ without the A-site cation can also form these hexagonal phases. The presence of hexagonal phases limits the use of pure FAPbI₃ as the absorber layer in PSCs due to its indirect and large band gap of around 2.4 eV. Moreover, studies have shown that once the α-FAPbI₃ perovskite is formed at high temperatures, it is stable at room temperature in an inert environment.

Improved methods for fabricating perovskite solar cells by thermal evaporation are needed, in particular methods that provide for a control of the perovskite phase(s) formed during thermal evaporation.

### SUMMARY

As described herein, substrate functionalization with phosphonic acids can be implemented to induce the growth of metal halide perovskites without the requirement of additional post-treatments. The phosphonic acids can induce the formation of cubic perovskites due to the interactions between the phosphonic acid and the organic A-site cation (e.g., formamidinium iodide). This A-site cation is an important component of the active perovskite materials; however, it is poorly incorporated in the absence of the phosphonic acid.

For example, herein we investigate the role of the substrate functionalization on the phase purity and composition of the co-evaporated FAPbI₃ layer. To understand the growth mechanisms of the cubic phase, a selection of phosphonic acids with distinct ligands was systematically employed to functionalize FTO substrates. These modified substrates were subsequently integrated into the thermal evaporation process. Our findings revealed the formation of a mixture of hexagonal phases on substrates without functionalization. The presence of these phases is potentially linked to a deficiency of FA⁺ within the layer, as suggested by our XPS measurements. Intriguingly, the introduction of some phosphonic acids increases the sorption rate of the organic cation onto the substrate, creating an environment that facilitates the production of pristine cubic-phase films. A key discovery is the role of phosphonic acid molecule migration through the perovskite layer. This phenomenon leads to a consistent increase in FAI sorption rate throughout the entire evaporation process, favoring the growth of cubic-phase films.

Accordingly, provided herein are methods of preparing semiconducting perovskite films, including perovskite solar cells. These methods can comprise depositing a layer comprising one or more phosphonic acids on a substrate to form a functionalization layer disposed on the substrate; and evaporating one or more precursor materials on the functionalization layer to form an active layer comprising a semiconducting perovskite material disposed on the functionalized layer.

In some embodiments, the substrate comprises an optically transparent material (e.g., a conductive oxide, such as fluorine-doped tin oxide (FTO) or indium tin oxide (ITO)).

In some embodiments, the functionalization later has a thickness greater than a monolayer. For example, in certain embodiments, the functionalization layer has a thickness of from 1 nm to 250 nm.

In some embodiments, depositing the layer comprising one or more phosphonic acids on the substrate comprises spin coating the one or more phosphonic acids, dip coating one or more phosphonic acids, spray coating one or more phosphonic acids, ink jet printing one or more phosphonic acids, or a combination thereof. In certain embodiments, depositing the layer comprising one or more phosphonic acids on the substrate comprises spin coating the one or more phosphonic acids.

In some embodiments, the one or more phosphonic acids comprise a phosphonic acid defined by the formula below

R—PO—(OH)₂

where R represents a C₁-C₈ alkyl group.

In certain embodiments, the one or more phosphonic acids comprise methyl phosphonic acid, propylphosphonic acid (PPAc), isopropylphosphonic acid, ethylphosphonic acid (EPAc), butyl phosphonic acid, tert-butyl phosphonic acid, pentyl phosphonic acid, hexyl phosphonic acid, or a combination thereof.

In some embodiments, the one or more precursor materials comprises an organic component and an inorganic component.

In some embodiments, the organic component comprises an organic monovalent defined by the formula [R¹R²N—CH═NR³R⁴]⁺:

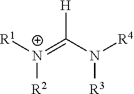

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group. In certain embodiments, the organic component comprises a formamidinium salt, such as formamidinium iodide, or a methylammonium salt, such as methylammonium iodide.

In some embodiments, the inorganic component comprises Pb, Sn, Ge, Si, Ti, Bi, In, or a combination thereof. In certain embodiments, the inorganic component comprises a lead halide, such as PbI₂.

In some embodiments, the evaporating one or more precursor materials on the functionalization layer comprises simultaneous vapor phase deposition of the organic component and the inorganic component.

In some embodiments, the organic component and the inorganic component are each deposited at a deposition rate of from 0.2 Å/second to 0.8 Å/second.

In some embodiments, the evaporation is continued until the active layer has a thickness of from 100 nm to 100 μm.

In some embodiments, the semiconducting perovskite material exhibits a substantially cubic phase.

In some embodiments, the semiconducting perovskite material is substantially free of a δ-phase.

In some embodiments, the method further comprises rotating the substrate during evaporation of the one or more precursor materials on the functionalization layer to enhance uniformity of the active layer.

In some embodiments, the method further comprises coating the substrate with an electron transport layer (ETL) or a hole transport layer (HTL) prior to depositing the layer comprising the one or more phosphonic acids on the substrate. In certain embodiments, the method further comprises coating the substrate with the ETL, and the ETL comprises tin oxide, titanium oxide, zinc oxide, a fullerene-based material, or a combination thereof. In other embodiments, the method further comprises coating the substrate with the HTL, and the HTL comprises nickel oxide, vanadium oxide, spiro OMeTAD, poly[bis(4-phenyl)(2,4,6-trimethylphenyl)amine (PTAA), phosphonic acid based molecules such as ([2-(9H-carbazol-9-yl)ethyl]phosphonic acid (2PACz), or a combination thereof.

Also provided herein are compositions (e.g., semiconducting perovskite films, including perovskite solar cells) that comprise a substrate; a functionalization layer disposed on the substrate, wherein the functionalization layer comprises one or more phosphonic acids; and an active layer comprising a semiconducting perovskite material disposed on the functionalized layer.

In some embodiments, the functionalization layer has a thickness greater than a monolayer. In certain embodiments, the functionalization layer has a thickness of from 1 nm to 250 nm.

In some embodiments, the substrate comprises an optically transparent material. In certain embodiments, the substrate comprises a conductive oxide, such as fluorine-doped tin oxide (FTO) or indium tin oxide (ITO).

In some embodiments, the semiconducting perovskite material comprises an organometal halide perovskite material.

In some embodiments, the organometal halide perovskite material is defined by a general formula ABX₃, where A comprises at least one organic monovalent cation, B comprises at least one divalent inorganic cation, and X comprises at least one halide ion.

In some embodiments, the organic monovalent cation comprises a primary, secondary or tertiary ammonium cation [HNR¹R²R³]⁺, wherein each of R¹, R² and R³ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula [R¹R²N—CH═NR³R⁴]⁺:

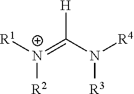

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula (R¹R²N)(R³R⁴N)C═NR⁵R⁶:

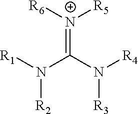

wherein each of R¹R², R³, R⁵ and R⁶ may be the same or different and is selected from hydrogen, an unsubstituted or substituted C₁-C₂₀ alkyl group and an unsubstituted or substituted C₅-C₁₈ aryl group.

In certain embodiments, the organic monovalent cation comprises a formamidinium cation.

In some embodiments, A further comprises a monovalent metal cation. In some embodiments, the monovalent cation comprises an alkali metal cation. In some embodiments, A further comprises one or more of Cs⁺, Rb⁺, Cu⁺, Pd⁺, Pt⁺, Ag⁺, Au⁺, Rh⁺, and Ru.

In some embodiments, the divalent cation B comprises a divalent metal cation. In some embodiments, the divalent metal cation comprises Sn²⁺, Pb²⁺, Ge²⁺, or any combination thereof.

In some embodiments, X is chloride, bromide, iodide, fluoride, or a combination thereof. In certain embodiments, X is bromide, iodide, or a combination thereof.

In some embodiments, the organometal halide perovskite material has an A₁₋ᵢA′ᵢBX₃ structure, wherein: A and A′ are each a monovalent cation, where A and A′ are different, and wherein at least one of A and A′ is an organic monovalent cation; B is a divalent cation; X is a halide anion; and i is between 0 and 1.

In some embodiments, the organometal halide perovskite material has an ABX₃₋ₖ X′ₖ structure, wherein: A is an organic monovalent cation; B is a divalent cation; X and X′ are each a halide anion, where X and X′ are different; and k is between 0 and 3.

In some embodiments, the organometal halide perovskite material has an AB₁₋ᵢB′ⱼX₃ structure, wherein: A is an organic monovalent cation; B and B′ are each a divalent cation, wherein B and B′ are different; X is a halide anion; and j is between 0 and 1.

In some embodiments, the organometal halide perovskite material has an Aᵢ₋₁A′ᵢB₁₋ⱼB′jX₃₋ₖX′ₖ structure, wherein: A and A′ are each a monovalent cation, where A and A′ are different, and wherein at least one of A and A′ is an organic monovalent cation; B and B′ are each a divalent cation, wherein B and B′ are different; X and X′ are each a halide anion, where X and X′ are different; and where i is between 0 and 1, j is between 0 and 1, and k is between 0 and 3.

In some embodiments, the semiconducting perovskite material exhibits a substantially cubic phase.

In some embodiments, the semiconducting perovskite material is substantially free of a δ-phase.

In some embodiments, the one or more phosphonic acids comprise methyl phosphonic acid, propylphosphonic acid (PPAc), ethylphosphonic acid (EPAc), 3-bromopropyl phosphonic acid (3BrPPAc), 3-phosphonopropionic acid (3PPAc), butyl phosphonic acid, pentyl phosphonic acid, hexyl phosphonic acid, or a combination thereof.

In some embodiments, the substrate is coated with an electron transport layer (ETL). In certain embodiments, the ETL comprises tin oxide, titanium oxide, zinc oxide, a fullerene-based material, or a combination thereof.

In some embodiments, the substrate is coated with a hole transport layer (HTL). In certain embodiments, the HTL comprises nickel oxide, vanadium oxide, spiro OMeTAD, poly[bis(4-phenyl)(2,4,6-trimethylphenyl)amine (PTAA), phosphonic acid based molecules such as ([2-(9H-carbazol-9-yl)ethyl]phosphonic acid (2PACz), or a combination thereof.

### BRIEF DESCRIPTION OF THE DRAWINGS

FIGS. 1A-1E illustrate the growth of PbI₂ and FAPI₃ hexagonal phases on FTO. FIG. 1A shows a schematic of the evaporation process. FIG. 1B shows photographic documentation of the evolution of the films with the annealing time at 150° C. FIG. 1C shows circular integration of the GIWAXS pattern of the as-deposited FAPbI₃ film. The 2H labels belong to FAPI₃ and * indicates the position of XRD peaks incompatible with the 6-FAPI₃ phase and suggests the presence of other hexagonal polytypes from both PbI₂ and FAPI₃. FIG. 1D shows the cathodoluminescence spectrum of the as-deposited FAPbI₃ film. FIG. 1E shows the evolution of the circular integration of the GIWAXS patterns FAPbI₃ films at varying annealing times at 150° C.

FIGS. 2A-2G illustrate the growth mechanisms of α-FAPbI₃ on substrates treated with PPAc molecules. FIG. 2A is a schematic illustrating substrate treatment with select phosphonic acids. FIG. 2B is a comparison of the XRD patterns of FAPbI₃ films on substrates with and without PPAc (3 mM in ethanol) treatment. FIG. 2C is a model of the growth energies as a function of FAPbI₃ layer thickness (h) with PPAc and 3PPAc molecules. A denser network of stronger H-bonds between FA and terminal iodines in 2H is shown in FIG. 2D as compared to α phase as shown in FIG. 2F. The interactions between the PAc and terminal FA in the 2H-FAPbI₃ phase shown in FIG. 2E are weaker than in the α-FAPbI₃ phase shown in FIG. 2G, which show stronger hydrogen bond formation (H . . . O=1.8 Å). All bond lengths are given in Å with the threshold of 3.1 Å.

FIGS. 3A-3C show the optical properties and morphology assessment of thin films. FIG. 3A shows the UV-vis absorption spectra of FAPbI₃ films on substrates with and without PPAc treatment. FIG. 3B shows the CL spectra of FAPbI₃ films on substrates with and without PPAc treatment. FIG. 3C shows SEM images of FAPbI₃ films on substrates with and without PPAc treatment. Scale bar is 1 μm.

FIGS. 4A-4D illustrates the effect of concentration of PAc solution and ethanol wash on the phase purity. FIG. 4A shows the Br 3d peak area of 3BrPPAc-treated substrates with and without ethanol wash as measured by XPS. FIG. 4B shows a comparison of XRD patterns of films deposited on PPAc-treated substrates with and without ethanol wash. FIG. 4C shows pictures of FAPbI₃ films deposited on substrates treated with varying concentrations and PAc molecules. FIG. 4D is a plot showing the ratio of measured thickness (t_{Measured}) on substrates to the predicted thickness by the QCM (t_{QCM}) for FAPbI₃ films deposited on substrates treated with varying concentrations and PAc molecules.

FIGS. 5A-5B show ball and stick models of the bilayer of PAc molecules functionalizing the FTO surface. FIG. 5A shows FTO-PPAc—PPAc binding modes. FIG. 5B shows FTO-3PPAc-3PPAc binding modes. For clarity, only the top layer of FTO is shown.

FIGS. 6A-6D illustrate the deposition of FAI on bare and treated QCMs. FIG. 6A is a schematic of the experimental setup. FIGS. 6B and 6B show the QCM mass flux for samples without treatment (FIG. 6B) and with PPAc treatment (FIG. 6C). FIG. 6D shows XPS P 2p scan measurements of QCMs with and without PPAc treatment after deposition of 200 nm of FAI.

FIG. 7 illustrates the proposed mechanism for the growth of α-FAPbI₃ on phosphonic acid-treated substrates.

FIGS. 8A-8B show the results of stability tests performed under nitrogen and humid air.

FIG. 8A shows photographs of thin films on FTO glass before and after exposure to saturated humid air (˜80% relative humidity). FIG. 8B shows XRD patterns of the film as deposited, after 11 months in a N₂ box, and after 24 h of exposure to saturated humid air.

FIG. 9 is a schematic illustration of the use of phosphonic acids to stabilize cubic FAPbI₃ when deposited by thermal evaporation.

FIGS. 10A-10D show the GIWAXS patterns of FAPbI₃ films deposited on bare FTO and annealed at 150° C. for varying times. FIG. 10A shows the GIWAXS pattern of an as-deposited FAPbI₃ film on bare FTO. FIG. 10B shows the GIWAXS pattern of a FAPbI₃ film on bare FTO and annealed at 150° C. for 15 minutes. FIG. 10C shows the GIWAXS pattern of a FAPbI₃ film on bare FTO and annealed at 150° C. for 1 hour. FIG. 10D shows the GIWAXS pattern of a FAPbI₃ film on bare FTO and annealed at 150° C. for 3 hours.

FIG. 11 shows the circular integration of GIWAXS pattern of FAPbI₃ evaporated on bare FTO (top trace) and comparison with simulated patterns for the possible phases.

FIG. 12 shows the XRD pattern of as-deposited FAPbI₃ film of bare FTO, revealing the presence of the 2H FAPbI₃ polytype, as evidenced by the presence of the characteristic peak of the (100) plane at 2θ=11.65°. Additionally, a small amount of the cubic phase, α-FAPbI₃, was detected with a peak observed at 2θ=13.9°. However, a peak at 2θ=12.5° exhibited the highest intensity, suggesting that another non-perovskite phase constitutes the majority of the film. This peak could potentially be associated with either PbI₂ or other hexagonal polytypes, such as 4H and 6H. Peaks from the 6H—PbI₂ phase match with the positions of the peaks marked with an *. However, precise phase identification is difficult in polycrystalline thin films due to the overlap of the peaks between all the phases and the low signal of the peaks at higher angles.

FIG. 13 shows CL-SEM intensity maps and point CL spectra of co-evaporated films on bare FTO.

FIG. 14 shows XRD patterns of FAPbI₃ films on bare FTO annealed by varying time. The *-marked peak is associated with hexagonal PbI₂ or FAPbI₃ polytypes.

FIG. 15 shows UV-VIS spectroscopy of FAPbI₃ films on bare FTO annealed by varying time.

FIG. 16 shows XRD patterns of FAPbI₃ films on FTO functionalized with different functional groups on the R-ligand of the phosphonic acid and concentration of 5 mM. The peaks for PPAc and EPAc match closely those of the α-FAPbI₃ at around 2θ=13.9° whereas the rest of the Pac molecules produce a combination of both α-FAPbI₃ and hexagonal phases, with peaks at 2θ=12.5° and 11.6°.

FIG. 17 shows a proposed capping mechanism of FAPbI₃ via phosphonic acids. Ball and stick models of PPAc (a, c, e, g) and 3PPAc (b, d, f, h) phosphonic acids capping FAI-terminated slabs of α-(upper panel) and 2H-FAPbI₃ (lower panel) both via PA (a, b, c, d), CH₃ of PPAc (e, g) and COOH of 3PPAc (f, h) are shown. Dashed lines indicate H-bonds between H of terminal FA and O of phosphonate (a, b) as well as O of carboxyl group (d, h). O, C, N, H, P, Pb and I atoms are depicted as red, brown, light blue, white, lavender, grey and magenta spheres, respectively. For clarity, only the top few layers of the slabs are shown.

FIG. 18 shows a proposed capping mechanism of FAPbI₃ via phosphonic acids. Ball and stick models of PPAc (a, c, e, g) and 3PPAc (b, d, f, h) phosphonic acids capping PbI₂-terminated slabs of α-(upper panel) and 2H-FAPbI₃ (lower panel) via PA (a, b, c, d), CH₃ of PPAc (e, g) and COOH of 3PPAc (f, h) are shown. O, C, N, H, P, Pb and I atoms are depicted as red, brown, light blue, white, lavender, grey and magenta spheres, respectively. For clarity, only the top few layers of the slabs are shown.

FIG. 19 illustrates the growth energy, E_{g} (eV/Å²), for PAc-capped PbI₂-terminated FAPbI₃ versus the grown thickness (h) obtained via Eq. 4. The energy terms for each capped slab model are provided in Table 1.

FIG. 20 shows CL-SEM intensity maps and point CL spectra of co-evaporated films on 3 mM PPac.

FIG. 21 shows XRD patterns of FAPbI₃ films deposited on 3BrPPAc functionalized substrate with varying concentration. H=hexagonal phases.

FIG. 22 shows XRD patterns of FAPbI₃ films deposited on EPAc functionalized substrate with varying concentration.

FIG. 23 shows XRD patterns of FAPbI₃ films deposited on PPAc functionalized substrate with varying concentration.

FIGS. 24A-24D show the XPS analysis for Perovskite films deposited on substrates functionalized with different concentrations of PPAc molecules. FIG. 24A shows a N is scan.

FIG. 24B shows a O 1s scan. FIG. 24C shows the I/Pb elemental ratio. FIG. 24D shows the N/Pb elemental ratio.

FIG. 25 shows the integration of P 2p XPS peak on FAI thin films (200 nm) deposited via thermal evaporation on Si/Au/phosphonic acid substrates.

FIGS. 26A-26D show XRD patterns of FAPbI₃ films deposited using varying methods and on varying substrates. FIG. 26A shows the XRD pattern of FAPbI₃ films deposited by spin-coating (from solution) on bare FTO. FIG. 26B shows the XRD pattern of FAPbI₃ films deposited by evaporation on bare FTO. FIG. 26C shows the XRD pattern of FAPbI₃ films deposited on 3PPAc treated FTO. FIG. 26D shows the XRD pattern of FAPbI₃ films deposited on PPAc treated FTO.

### DETAILED DESCRIPTION

### Definitions

Terms used herein will have their customary meaning in the art unless specified otherwise. The organic moieties mentioned when defining variable positions within the general formulae described herein (e.g., the term “halogen”) are collective terms for the individual substituents encompassed by the organic moiety. The prefix Cn-Cm indicates in each case the possible number of carbon atoms in the group.

The term “alkyl,” as used herein, refers to saturated straight, branched, cyclic, primary, secondary or tertiary hydrocarbons, including those having 1 to 20 atoms. In some embodiments, alkyl groups will include C₁-C₁₂, C₁-C₁₀, C₁-C₈, C₁-C₆, C₁-C₅, C₁-C₄, C₁-C₃, C₁-C₂, or C₁ alkyl groups. Examples of C₁-C₁₀ alkyl groups include, but are not limited to, methyl, ethyl, propyl, 1-methylethyl, butyl, 1-methylpropyl, 2-methylpropyl, 1,1-dimethylethyl, pentyl, 1-methylbutyl, 2-methylbutyl, 3-methylbutyl, 2,2-dimethylpropyl, 1-ethylpropyl, hexyl, 1,1-dimethylpropyl, 1,2-dimethylpropyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, 1-ethyl-2-methylpropyl, heptyl, octyl, 2-ethylhexyl, nonyl and decyl groups, as well as their isomers. Examples of C₁-C₄-alkyl groups include, for example, methyl, ethyl, propyl, 1-methylethyl, butyl, 1-methylpropyl, 2-methylpropyl and 1,1-dimethylethyl groups.

Cyclic alkyl groups or “cycloalkyl” groups, which are encompassed alkyl, include cycloalkyl groups having from 3 to 10 carbon atoms. Cycloalkyl groups can include a single ring, or multiple condensed rings. In some embodiments, cycloalkyl groups include C₃-C₄, C₄-C₇, C₅-C₇, C₄-C₆, or C₅-C₆ cyclic alkyl groups. Non-limiting examples of cycloalkyl groups include adamantyl, cyclopropyl, cyclobutyl, cyclopentyl, cyclohexyl, cycloheptyl, cyclooctyl and the like.

Alkyl groups can be unsubstituted or substituted with one or more moieties selected from the group consisting of alkyl, halo, haloalkyl, hydroxyl, carboxyl, acyl, acyloxy, amino, alkyl- or dialkylamino, amido, arylamino, alkoxy, aryloxy, nitro, cyano, azido, thiol, imino, sulfonic acid, sulfate, sulfonyl, sulfanyl, sulfinyl, sulfamonyl, ester, phosphonyl, phosphinyl, phosphoryl, phosphine, thioester, thioether, acid halide, anhydride, oxime, hydrazine, carbamate, phosphoric acid, phosphate, phosphonate, or any other viable functional group that does not inhibit the biological activity of the compounds of the invention, either unprotected, or protected as necessary, as known to those skilled in the art, for example, as described in Greene, et al., Protective Groups in Organic Synthesis, John Wiley and Sons, Third Edition, 1999, hereby incorporated by reference.

Terms including the term “alkyl,” such as “alkylcycloalkyl,” “cycloalkylalkyl,” “alkylamino,” or “dialkylamino,” will be understood to comprise an alkyl group as defined above linked to another functional group, where the group is linked to the compound through the last group listed, as understood by those of skill in the art.

The term “alkenyl,” as used herein, refers to both straight and branched carbon chains which have at least one carbon-carbon double bond. In some embodiments, alkenyl groups can include C₂-C₂₀ alkenyl groups. In other embodiments, alkenyl can include C₂-C₁₂, C₂-C₁₀, C₂-C₈, C₂-C₆ or C₂-C₄ alkenyl groups. In one embodiment of alkenyl, the number of double bonds is 1-3, in another embodiment of alkenyl, the number of double bonds is one or two. Other ranges of carbon-carbon double bonds and carbon numbers are also contemplated depending on the location of the alkenyl moiety on the molecule. “C₂-C₁₀-alkenyl” groups may include more than one double bond in the chain. The one or more unsaturations within the alkenyl group may be located at any position(s) within the carbon chain as valence permits. In some embodiments, when the alkenyl group is covalently bound to one or more additional moieties, the carbon atom(s) in the alkenyl group that are covalently bound to the one or more additional moieties are not part of a carbon-carbon double bond within the alkenyl group. Examples of alkenyl groups include, but are not limited to, ethenyl, 1-propenyl, 2-propenyl, 1-methyl-ethenyl, 1-butenyl, 2-butenyl, 3-butenyl, 1-methyl-1-propenyl, 2-methyl-1-propenyl, 1-methyl-2-propenyl, 2-methyl-2-propenyl; 1-pentenyl, 2-pentenyl, 3-pentenyl, 4-pentenyl, 1-methyl-1-butenyl, 2-methyl-1-butenyl, 3-methyl-1-butenyl, 1-methyl-2-butenyl, 2-methyl-2-butenyl, 3-methyl-2-butenyl, 1-methyl-3-butenyl, 2-methyl-3-butenyl, 3-methyl-3-butenyl, 1,1-dimethyl-2-propenyl, 1,2-dimethyl-1-propenyl, 1,2-dimethyl-2-propenyl, 1-ethyl-1-propenyl, 1-ethyl-2-propenyl, 1-hexenyl, 2-hexenyl, 3-hexenyl, 4-hexenyl, 5-hexenyl, 1-methyl-1-pentenyl, 2-methyl-1-pentenyl, 3-methyl-1-pentenyl, 4-methyl-1-pentenyl, 1-methyl-2-pentenyl, 2-methyl-2-pentenyl, 3-methyl-2-pentenyl, 4-methyl-2-pentenyl, 1-methyl-3-pentenyl, 2-methyl-3-pentenyl, 3-methyl-3-pentenyl, 4-methyl-3-pentenyl, 1-methyl-4-pentenyl, 2-methyl-4-pentenyl, 3-methyl-4-pentenyl, 4-methyl-4-pentenyl, 1,1-dimethyl-2-butenyl, 1,1-dimethyl-3-butenyl, 1,2-dimethyl-1-butenyl, 1,2-dimethyl-2-butenyl, 1,2-dimethyl-3-butenyl, 1,3-dimethyl-1-butenyl, 1,3-dimethyl-2-butenyl, 1,3-dimethyl-3-butenyl, 2,2-dimethyl-3-butenyl, 2,3-dimethyl-1-butenyl, 2,3-dimethyl-2-butenyl, 2,3-dimethyl-3-butenyl, 3,3-dimethyl-1-butenyl, 3,3-dimethyl-2-butenyl, 1-ethyl-1-butenyl, 1-ethyl-2-butenyl, 1-ethyl-3-butenyl, 2-ethyl-1-butenyl, 2-ethyl-2-butenyl, 2-ethyl-3-butenyl, 1,1,2-trimethyl-2-propenyl, 1-ethyl-1-methyl-2-propenyl, 1-ethyl-2-methyl-1-propenyl and 1-ethyl-2-methyl-2-propenyl groups.

The term “alkynyl,” as used herein, refers to both straight and branched carbon chains which have at least one carbon-carbon triple bond. In one embodiment of alkynyl, the number of triple bonds is 1-3; in another embodiment of alkynyl, the number of triple bonds is one or two.

In some embodiments, alkynyl groups include from C₂-C₂₀ alkynyl groups. In other embodiments, alkynyl groups may include C₂-C₁₂, C₂-C₁₀, C₂-C₈, C₂-C₆ or C₂-C₄ alkynyl groups.

Other ranges of carbon-carbon triple bonds and carbon numbers are also contemplated depending on the location of the alkenyl moiety on the molecule. For example, the term “C₂-C₁₀-alkynyl” as used herein refers to a straight-chain or branched unsaturated hydrocarbon group having 2 to 10 carbon atoms and containing at least one triple bond, such as ethynyl, prop-1-yn-1-yl, prop-2-yn-1-yl, n-but-1-yn-1-yl, n-but-1-yn-3-yl, n-but-1-yn-4-yl, n-but-2-yn-1-yl, n-pent-1-yn-1-yl, n-pent-1-yn-3-yl, n-pent-1-yn-4-yl, n-pent-1-yn-5-yl, n-pent-2-yn-1-yl, n-pent-2-yn-4-yl, n-pent-2-yn-5-yl, 3-methylbut-1-yn-3-yl, 3-methylbut-1-yn-4-yl, n-hex-1-yn-1-yl, n-hex-1-yn-3-yl, n-hex-1-yn-4-yl, n-hex-1-yn-5-yl, n-hex-1-yn-6-yl, n-hex-2-yn-1-yl, n-hex-2-yn-4-yl, n-hex-2-yn-5-yl, n-hex-2-yn-6-yl, n-hex-3-yn-1-yl, n-hex-3-yn-2-yl, 3-methylpent-1-yn-1-yl, 3-methylpent-1-yn-3-yl, 3-methylpent-1-yn-4-yl, 3-methylpent-1-yn-5-yl, 4-methylpent-1-yn-1-yl, 4-methylpent-2-yn-4-yl, and 4-methylpent-2-yn-5-yl groups.

The term “haloalkyl” or “alkylhalide,” as used herein refers to an alkyl group, as defined above, which is substituted by one or more halogen atoms. In some instances, the haloalkyl group can be an alkyl group substituted by one or more fluorine atoms. In certain instances, the haloalkyl group can be a perfluorinated alkyl group. For example, C₁-C₄-haloalkyl includes, but is not limited to, chloromethyl, bromomethyl, dichloromethyl, trichloromethyl, fluoromethyl, difluoromethyl, trifluoromethyl, chlorofluoromethyl, dichlorofluoromethyl, chlorodifluoromethyl, 1-chloroethyl, 1-bromoethyl, 1-fluoroethyl, 2-fluoroethyl, 2,2-difluoroethyl, 2,2,2-trifluoroethyl, 2-chloro-2-fluoroethyl, 2-chloro-2,2-difluoroethyl, 2,2-dichloro-2-fluoroethyl, 2,2,2-trichloroethyl, and pentafluoroethyl.

The term “alkoxy,” as used herein, refers to alkyl-O—, wherein alkyl refers to an alkyl group, as defined above. Similarly, the terms “alkenyloxy,” “alkynyloxy,” “haloalkoxy,” “haloalkenyloxy,” “haloalkynyloxy,” “cycloalkoxy,” “cycloalkenyloxy,” “halocycloalkoxy,” and “halocycloalkenyloxy” refer to the groups alkenyl-O—, alkynyl-O—, haloalkyl-O—, haloalkenyl-O—, haloalkynyl-O—, cycloalkyl-O—, cycloalkenyl-O—, halocycloalkyl-O—, and halocycloalkenyl-O—, respectively, wherein alkenyl, alkynyl, haloalkyl, haloalkenyl, haloalkynyl, cycloalkyl, cycloalkenyl, halocycloalkyl, and halocycloalkenyl are as defined above. Examples of C₁-C₆-alkoxy include, but are not limited to, methoxy, ethoxy, C₂H₅—CH₂O—, (CH₃)₂CHO—, n-butoxy, C₂H₅—CH(CH₃)O—, (CH₃)₂CH—CH₂O—, (CH₃)₃CO—, n-pentoxy, 1-methylbutoxy, 2-methylbutoxy, 3-methylbutoxy, 1,1-dimethylpropoxy, 1,2-dimethylpropoxy, 2,2-dimethyl-propoxy, 1-ethylpropoxy, n-hexoxy, 1-methylpentoxy, 2-methylpentoxy, 3-methylpentoxy, 4-methylpentoxy, 1,1-dimethylbutoxy, 1,2-dimethylbutoxy, 1,3-dimethylbutoxy, 2,2-dimethylbutoxy, 2,3-dimethylbutoxy, 3,3-dimethylbutoxy, 1-ethylbutoxy, 2-ethylbutoxy, 1,1,2-trimethylpropoxy, 1,2,2-trimethylpropoxy, 1-ethyl-1-methylpropoxy, and 1-ethyl-2-methylpropoxy.

The terms “alkylamino” and “dialkylamino,” as used herein, refer to alkyl-NH— and (alkyl)₂N-groups, where alkyl is as defined above. Similarly, the terms “haloalkylamino” and “halodialkylamino” refer to haloalkyl-NH— and (haloalkyl)₂-NH—, where haloalkyl is as defined above.

The term “aryl,” as used herein, refers to a monovalent aromatic carbocyclic group of from 6 to 14 carbon atoms. Aryl groups can include a single ring or multiple condensed rings. In some embodiments, aryl groups include C₆-C₁₀ aryl groups. Aryl groups include, but are not limited to, phenyl, biphenyl, naphthyl, tetrahydronaphtyl, phenylcyclopropyl and indanyl. Aryl groups may be unsubstituted or substituted by one or more moieties selected from halogen, cyano, nitro, hydroxy, mercapto, amino, alkyl, alkenyl, alkynyl, cycloalkyl, cycloalkenyl, haloalkyl, haloalkenyl, haloalkynyl, halocycloalkyl, halocycloalkenyl, alkoxy, alkenyloxy, alkynyloxy, haloalkoxy, haloalkenyloxy, haloalkynyloxy, cycloalkoxy, cycloalkenyloxy, halocycloalkoxy, halocycloalkenyloxy, alkylthio, haloalkylthio, cycloalkylthio, halocycloalkylthio, alkylsulfinyl, alkenylsulfinyl, alkynyl-sulfinyl, haloalkylsulfinyl, haloalkenylsulfinyl, haloalkynylsulfinyl, alkylsulfonyl, alkenylsulfonyl, alkynylsulfonyl, haloalkyl-sulfonyl, haloalkenylsulfonyl, haloalkynylsulfonyl, alkylamino, alkenylamino, alkynylamino, di(alkyl)amino, di(alkenyl)-amino, di(alkynyl)amino, or trialkylsilyl.

The term “alkylaryl,” as used herein, refers to an aryl group that is bonded to a parent compound through a diradical alkylene bridge, (—CH₂—)ₙ, where n is 1-12 and where “aryl” is as defined above.

The term “alkylcycloalkyl,” as used herein, refers to a cycloalkyl group that is bonded to a parent compound through a diradical alkylene bridge, (—CH₂—)ₙ, where n is 1-12 and where “cycloalkyl” is as defined above. The term “cycloalkylalkyl,” as used herein, refers to a cycloalkyl group, as defined above, which is substituted by an alkyl group, as defined above.

The term “heteroaryl,” as used herein, refers to a monovalent aromatic group of from 1 to 15 carbon atoms (e.g., from 1 to 10 carbon atoms, from 2 to 8 carbon atoms, from 3 to 6 carbon atoms, or from 4 to 6 carbon atoms) having one or more heteroatoms within the ring. The heteroaryl group can include from 1 to 4 heteroatoms, from 1 to 3 heteroatoms, or from 1 to 2 heteroatoms. In some cases, the heteroatom(s) incorporated into the ring are oxygen, nitrogen, sulfur, or combinations thereof. When present, the nitrogen and sulfur heteroatoms may optionally be oxidized. Heteroaryl groups can have a single ring (e.g., pyridyl or furyl) or multiple condensed rings provided that the point of attachment is through a heteroaryl ring atom. Preferred heteroaryls include pyridyl, pyridazinyl, pyrimidinyl, pyrazinyl, triazinyl, pyrrolyl, indolyl, quinolinyl, isoquinolinyl, quinazolinyl, quinoxalinyl, furanyl, thiophenyl, furyl, pyrrolyl, imidazolyl, oxazolyl, isoxazolyl, isothiazolyl, pyrazolyl, benzofuranyl, and benzothiophenyl. Heteroaryl rings may be unsubstituted or substituted by one or more moieties as described for aryl above.

The term “alkylheteroaryl,” as used herein, refers to a heteroaryl group that is bonded to a parent compound through a diradical alkylene bridge, (—CH₂—)ₙ, where n is 1-12 and where “heteroaryl” is as defined above.

The terms “cycloheteroalkyl,” “heterocyclyl,” “heterocyclic,” and “heterocyclo” are used herein interchangeably, and refer to fully saturated or unsaturated, cyclic groups, for example, 3- to 7-membered monocyclic or 4- to 7-membered monocyclic; 7- to 11-membered bicyclic, or 10- to 15-membered tricyclic ring systems, having one or more heteroatoms within the ring. The heterocyclyl group can include from 1 to 4 heteroatoms, from 1 to 3 heteroatoms, or from 1 to 2 heteroatoms. In some cases, the heteroatom(s) incorporated into the ring are oxygen, nitrogen, sulfur, or combinations thereof. When present, the nitrogen and sulfur heteroatoms may optionally be oxidized, and the nitrogen heteroatoms may optionally be quaternized. The heterocyclyl group may be attached at any heteroatom or carbon atom of the ring or ring system and may be unsubstituted or substituted by one or more moieties as described for aryl groups above.

Exemplary monocyclic heterocyclic groups include, but are not limited to, pyrrolidinyl, pyrrolyl, pyrazolyl, oxetanyl, pyrazolinyl, imidazolyl, imidazolinyl, imidazolidinyl, oxazolyl, oxazolidinyl, isoxazolinyl, isoxazolyl, thiazolyl, thiadiazolyl, thiazolidinyl, isothiazolyl, isothiazolidinyl, furyl, tetrahydrofuryl, thienyl, oxadiazolyl, piperidinyl, piperazinyl, 2-oxopiperazinyl, 2-oxopiperidinyl, 2-oxopyrrolodinyl, 2-oxoazepinyl, azepinyl, 4-piperidonyl, pyridinyl, pyrazinyl, pyrimidinyl, pyridazinyl, tetrahydropyranyl, morpholinyl, thiamorpholinyl, thiamorpholinyl sulfoxide, thiamorpholinyl sulfone, 1,3-dioxolane and tetrahydro-1,1-dioxothienyl, triazolyl, triazinyl, and the like.

The term “alkylheterocyclyl” and “alkylcycloheteroalkyl” are used herein interchangeably, and refer to a heterocyclyl group that is bonded to a parent compound through a diradical alkylene bridge, (—CH₂—)ₙ, where n is 1-12 and where “heterocyclyl” is as defined above. The term “heterocyclylalkyl,” as used herein, refers to a heterocyclyl group, as defined above, which is substituted by an alkyl group, as defined above.

The term “halogen,” as used herein, refers to the atoms fluorine, chlorine, bromine and iodine. The prefix halo-(e.g., as illustrated by the term haloalkyl) refers to all degrees of halogen substitution, from a single substitution to a perhalo substitution (e.g., as illustrated with methyl as chloromethyl (—CH₂Cl), dichloromethyl (—CHCl₂), trichloromethyl (—CCl₃)).

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc.

### Compositions

Provided herein are compositions that comprise: a substrate; a functionalization layer disposed on the substrate, wherein the functionalization layer comprises one or more phosphonic acids; and an active layer comprising a semiconducting perovskite material disposed on the functionalized layer.

In some embodiments, the functionalization layer can have a thickness greater than a monolayer.

In certain embodiments, the functionalization layer can have a thickness of at least 1 nm.

In some embodiments, the functionalization layer can have a thickness of at least 2 nm (e.g., at least 3 nm, at least 4 nm, at least 5 nm, at least 10 nm, at least 15 nm, at least 20 nm, at least 25 nm, at least 30 nm, at least 40 nm, at least 50 nm, at least 60 nm, at least 70 nm, at least 75 nm, at least 80 nm, at least 90 nm, at least 100 nm, at least 110 nm, at least 115 nm, at least 120 nm, at least 125 nm, at least 130 nm, at least 140 nm, at least 150 nm, at least 160 nm, at least 170 nm, at least 175 nm, at least 180 nm, at least 190 nm, at least 200 nm, at least 210 nm, at least 215 nm, at least 220 nm, at least 225 nm, at least 230 nm, or at least 240 nm).

In some embodiments, the functionalization layer can have a thickness of 250 nm or less (e.g., 240 nm or less, 230 nm or less, 225 nm or less, 220 nm or less, 210 nm or less, 200 nm or less, 190 nm or less, 180 nm or less, 175 nm or less, 170 nm or less, 160 nm or less, 150 nm or less, 140 nm or less, 130 nm or less, 125 nm or less, 120 nm or less, 110 nm or less, 100 nm or less, 90 nm or less, 80 nm or less, 75 nm or less, 70 nm or less, 60 nm or less, 50 nm or less, 40 nm or less, 30 nm or less, 25 nm or less, 20 nm or less, 10 nm or less, or 5 nm or less).

The functionalization layer can have a thickness ranging from any of the minimum values described above to any of the maximum values described above. For example, in some embodiments, the functionalization layer can have a thickness of from 1 nm to 250 nm (e.g., from 1 nm to 200 nm, from 1 nm to 150 nm, from 1 nm to 100 nm, from 1 nm to 50 nm, from 1 nm to 25 nm, from 5 nm to 250 nm, from 5 nm to 200 nm, from 5 nm to 150 nm, from 5 nm to 100 nm, from 5 nm to 50 nm, or from 5 nm to 25 nm).

The substrate can comprise any suitable substrate material. In some embodiments, the substrate can comprise an optically transparent material. In certain embodiments, the substrate can comprise a conductive oxide, such as fluorine-doped tin oxide (FTO) or indium tin oxide (ITO).

In some embodiments, the substrate can be coated with an electron transport layer (ETL). The ETL can comprise, for example, tin oxide, titanium oxide, zinc oxide, a fullerene-based material, or a combination thereof.

In other embodiments, the substrate can be coated with a hole transport layer (HTL). The HTL can comprise, for example, nickel oxide, vanadium oxide, spiro OMeTAD, poly[bis(4-phenyl)(2,4,6-trimethylphenyl)amine (PTAA), phosphonic acid based molecules such as ([2-(9H-carbazol-9-yl)ethyl]phosphonic acid (2PACz), or a combination thereof.

In some embodiments, the semiconducting perovskite material comprises an organometal halide perovskite material.

In some embodiments, the organometal halide perovskite material can be defined by a general formula ABX₃, where A comprises at least one organic monovalent cation, B comprises at least one divalent inorganic cation, and X comprises at least one halide ion.

In some embodiments, the organic monovalent cation comprises a primary, secondary or tertiary ammonium cation [HNR¹R²R³]⁺, wherein each of R¹, R² and R³ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula [R¹R²N—CH═NR³R⁴]⁺:

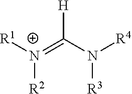

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula (R¹R²N)(R³R⁴N)C═NR⁵R⁶:

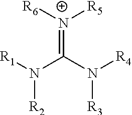

wherein each of R¹R², R³, R⁵ and R⁶ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises a formamidinium cation.

In some embodiments, A further comprises a monovalent metal cation. In certain embodiments, the monovalent cation comprises an alkali metal cation. In certain embodiments, A further comprises one or more of Cs⁺, Rb⁺, Cu⁺, Pd⁺, Pt⁺, Ag⁺, Au⁺, Rh⁺, and Ru.

In some embodiments, the divalent cation B comprises a divalent metal cation. In certain embodiments, the divalent metal cation comprises Sn²⁺, Pb²⁺, Ge²⁺, or any combination thereof.

In some embodiments, the X is chloride, bromide, iodide, fluoride, or a combination thereof. In certain embodiments, X is bromide, iodide, or a combination thereof.

In some embodiments, the organometal halide perovskite material has an A₁₋ᵢA′ᵢBX₃ structure, wherein: A and A′ are each a monovalent cation, where A and A′ are different, and wherein at least one of A and A′ is an organic monovalent cation; B is a divalent cation; X is a halide anion; and i is between 0 and 1.

In some embodiments, the organic monovalent cation comprises a primary, secondary or tertiary ammonium cation [HNR¹R²R³]⁺, wherein each of R¹, R² and R³ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula [R¹R²N—CH═NR³R⁴]⁺:

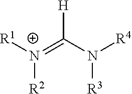

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula (R¹R²N)(R³R⁴N)C═NR⁵R⁶:

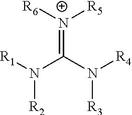

wherein each of R¹R², R³, R⁵ and R⁶ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises a formamidinium cation.

In some embodiments, one of A and A′ comprises a monovalent metal cation. In certain embodiments, the monovalent cation comprises an alkali metal cation. In certain embodiments, one of A and A′ comprises one or more of Cs⁺, Rb⁺, Cu⁺, Pd⁺, Pt⁺, Ag⁺, Au⁺, Rh⁺, and Ru.

In some embodiments, the divalent cation B comprises a divalent metal cation. In certain embodiments, the divalent metal cation comprises Sn²⁺, Pb²⁺, Ge²⁺, or any combination thereof.

In some embodiments, the X is chloride, bromide, iodide, fluoride, or a combination thereof. In certain embodiments, X is bromide, iodide, or a combination thereof.

In some embodiments, the organometal halide perovskite material has an ABX₃₋ₖX′ₖ structure, wherein: A is an organic monovalent cation; B is a divalent cation; X and X′ are each a halide anion, where X and X′ are different; and k is between 0 and 3.

In some embodiments, the organic monovalent cation comprises a primary, secondary or tertiary ammonium cation [HNR¹R²R³]⁺, wherein each of R¹, R² and R³ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula [R¹R²N—CH═NR³R⁴]⁺:

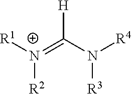

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula (R¹R²N)(R³R⁴N)C═NR⁵R⁶:

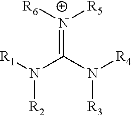

wherein each of R¹R², R³, R⁵ and R⁶ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises a formamidinium cation.

In some embodiments, A further comprises a monovalent metal cation. In certain embodiments, the monovalent cation comprises an alkali metal cation. In certain embodiments, A further comprises one or more of Cs⁺, Rb⁺, Cu⁺, Pd⁺, Pt⁺, Ag⁺, Au⁺, Rh⁺, and Ru.

In some embodiments, the divalent cation B comprises a divalent metal cation. In certain embodiments, the divalent metal cation comprises Sn², Pb²⁺, Ge²⁺, or any combination thereof.

In some embodiments, the X and X′ are each selected from chloride, bromide, iodide, and fluoride. In certain embodiments, X is bromide and X′ is iodide.

In some embodiments, the organometal halide perovskite material has an AB₁₋ᵢB′ⱼX₃ structure, wherein: A is an organic monovalent cation; B and B′ are each a divalent cation, wherein B and B′ are different; X is a halide anion; and j is between 0 and 1.

In some embodiments, the organic monovalent cation comprises a primary, secondary or tertiary ammonium cation [HNR¹R²R³]⁺, wherein each of R¹, R² and R³ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula [R¹R²N—CH═NR³R⁴]⁺:

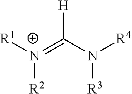

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula (R¹R²N)(R³R⁴N)C═NR⁵R⁶:

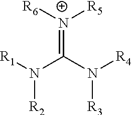

wherein each of R¹R², R³, R⁵ and R⁶ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises a formamidinium cation.

In some embodiments, A further comprises a monovalent metal cation. In certain embodiments, the monovalent cation comprises an alkali metal cation. In certain embodiments, A further comprises one or more of Cs⁺, Rb⁺, Cu⁺, Pd⁺, Pt⁺, Ag⁺, Au⁺, Rh⁺, and Ru.

In some embodiments, B and B′ each comprises a divalent metal cation. In certain embodiments, the divalent metal cation comprises Sn², Pb²⁺, Ge²⁺, or any combination thereof.

In some embodiments, the X is chloride, bromide, iodide, fluoride, or a combination thereof. In certain embodiments, X is bromide, iodide, or a combination thereof.

In some embodiments, the organometal halide perovskite material has an Aᵢ₋₁A′ᵢB₁₋ⱼB′jX₃₋ₖX′ₖ structure, wherein: A and A′ are each a monovalent cation, where A and A′ are different, and wherein at least one of A and A′ is an organic monovalent cation; B and B′ are each a divalent cation, wherein B and B′ are different; X and X′ are each a halide anion, where X and X′ are different; and where i is between 0 and 1, j is between 0 and 1, and k is between 0 and 3.

In some embodiments, the organic monovalent cation comprises a primary, secondary or tertiary ammonium cation [HNR¹R²R³]⁺, wherein each of R¹, R² and R³ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula [R¹R²N—CH═NR³R⁴]⁺:

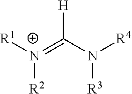

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises is defined by the formula (R¹R²N)(R³R⁴N)C═NR⁵R⁶:

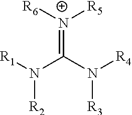

wherein each of R¹R², R³, R⁵ and R⁶ may be the same or different and is selected from hydrogen, an unsubstituted or substituted C₁-C₂₀ alkyl group and an unsubstituted or substituted C₅-C₁₈ aryl group.

In some embodiments, the organic monovalent cation comprises a formamidinium cation.

In some embodiments, one of A and A′ comprises a monovalent metal cation. In certain embodiments, the monovalent cation comprises an alkali metal cation. In certain embodiments, one of A and A′ comprises one or more of Cs⁺, Rb⁺, Cu⁺, Pd⁺, Pt⁺, Ag⁺, Au⁺, Rh⁺, and Ru.

In some embodiments, B and B′ each comprises a divalent metal cation. In certain embodiments, the divalent metal cation comprises Sn²⁺, Pb²⁺, Ge²⁺, or any combination thereof.

In some embodiments, the X and X′ are each selected from chloride, bromide, iodide, and fluoride. In certain embodiments, X is bromide and X′ is iodide.

In some embodiments, the semiconducting perovskite material exhibits a substantially cubic phase.

In some embodiments, the semiconducting perovskite material is substantially free of a δ-phase.

The phosphonic acid can comprise a variety of suitable phosphonic acids. In some examples, the phosphonic acid can comprise a phosphonic acid defined by the formula below

R—PO—(OH)₂

where R represents an organic moiety such as aryl (e.g., phenyl), heteroaryl, halogen-substituted aryl, halogen-substituted heteroaryl, alkoxy-substituted aryl (methoxyphenyl, ethoxyphenyl), alkoxy-substituted heteroaryl, cycloalkyl, alkyl, halogen-substituted alkyl, vinyl, allyl, benzyl, aminoalkyl, and hydroxyalkyl. Specific examples of phosphonic acids include methylphosphonic acid, ethylphosphonic acid, n-propylphosphonic acid, isopropylphosphonic acid, n-butylphosphonic acid, isobutylphosphonic acid, t-butylphosphonic acid, n-pentylphosphonic acid, neopentylphosphonic acid, cyclohexylphosphonic acid, benzylphosphonic acid, chloromethylphosphonic acid, dichloromethylphosphonic acid, bromomethylphosphonic acid, dibromomethylphosphonic acid, 2-chloroethylphosphonic acid, 1,2-dichloroethylphosphonic acid, 2-bromoethylphosphonic acid, 1,2-dibromoethylphosphonic acid, 3-chloropropylphosphonic acid, 2,3-dichloropropylphosphonic acid, 3-bromopropylphosphonic acid, 2,3-dibromopropylphosphonic acid, 2-chloro-1-methylethylphosphonic acid, 1,2-dichloro-1-methylethylphosphonic acid, 2-bromo-1-methylethylphosphonic acid, 1,2-dibromo-1-methylethylphosphonic acid, 4-chlorobutylphosphonic acid, 3,4-dichlorobutylphosphonic acid, 4-bromobutylphosphonic acid, 3,4-dibromobutylphosphonic acid, 3-chloro-1-methylpropylphosphonic acid, 2,3-dichloro-1-methylpropylphosphonic acid, 3-bromo-1-methylpropylphosphonic acid, 2,3-dibromo-1-methylphosphonic acid, 1-chloromethylpropylphosphonic acid, 1-chloro-1-chloromethylpropylphosphonic acid, 1-bromomethylpropylphosphonic acid, 1-bromo-1-bromomethylpropylphosphonic acid, 5-chloropentylphosphonic acid, 4,5-dichloropentylphosphonic acid, 5-bromopentylphosphonic acid, 4,5-dibromopentylphosphonic acid, 1-hydroxymethylphosphonic acid, 2-hydroxyethylphosphonic acid, 3-hydroxypropylphosphonic acid, 4-hydroxybutylphosphonic acid, 5-hydroxypentylphosphonic acid, 1-aminomethylphosphonic acid, 2-aminoethylphosphonic acid, 3-aminopropylphosphonic acid, 4-aminobutylphosphonic acid, 5-aminopentylphosphonic acid, methylthiomethylphosphonic acid, methylthioethylphosphonic acid, methylthiopropylphosphonic acid, methylthiobutylphosphonic acid, ethylthiomethylphosphonic acid, ethylthioethylphosphonic acid, ethylthiopropylphosphonic acid, propylthiomethylphosphonic acid, propylthioethylphosphonic acid, butylthiomethylphosphonic acid, phenylphosphonic acid, 4-chlorophenylphosphonic acid, 3,4-dichlorophenylphosphonic acid, 3,5-dichlorophenylphosphonic acid, 4-bromophenylphosphonic acid, 3,4-dibromophenylphosphonic acid, 3,5-dibromophenylphosphonic acid, 4-methoxyphenylphosphonic acid, 3,4-dimethoxyphenylphosphonic acid, 1-naphthylphosphonic acid, 2-naphthylphosphonic acid, benzylphosphonic acid, 4-bromophenylmethylphosphonic acid, 3,4-dibromophenylmethylphosphonic acid, 3,5-dibromophenylmethylphosphonic acid, 2-phenylethylphosphonic acid, 2-(4-bromophenyl)ethylphosphonic acid, 2-(3,4-dibromophenyl)ethylphosphonic acid, 2-(3,5-dibromophenyl)ethylphosphonic acid, 3-phenylpropylphosphonic acid, 3-(4-bromophenyl)propylphosphonic acid, 3-(3,4-dibromophenyl)propylphosphonic acid, 3-(3,5-dibromophenyl)propylphosphonic acid, 4-phenylbutylphosphonic acid, 4-(4-bromophenyl)butylphosphonic acid, 4-(3,4-dibromophenyl)butylphosphonic acid, 4-(3,5-dibromophenyl)butylphosphonic acid, 2-pyridylphosphonic acid, 3-pyridylphosphonic acid, 4-pyridylphosphonic acid, 1-pyrrolidinomethylphosphonic acid, 1-pyrrolidinoethylphosphonic acid, 1-pyrrolidinopropylphosphonic acid, 1-pyrrolidinobutylphosphonic acid, pyrrole-1-phosphonic acid, pyrrole-2-phosphonic acid, pyrrole-3-phosphonic acid, thiophene-2-phosphonic acid, thiophene-3-phosphonic acid, dithiane-2-phosphonic acid, trithiane-2-phosphonic acid, furan-2-phosphonic acid, furan-3-phosphonic acid, vinylphosphdnic acid, allylphosphonic acid, and 2-norbornylphosphonic acid.

In some embodiments, the one or more phosphonic acids comprise methyl phosphonic acid, propylphosphonic acid (PPAc), ethylphosphonic acid (EPAc), 3-bromopropyl phosphonic acid (3BrPPAc), 3-phosphonopropionic acid (3PPAc), butyl phosphonic acid, pentyl phosphonic acid, hexyl phosphonic acid, or a combination thereof.

In certain embodiments, the one or more phosphonic acids comprise a phosphonic acid defined by the formula below

R—PO—(OH)₂

where R represents a C₁-C₈ alkyl group.

In certain embodiments, the one or more phosphonic acids comprise methyl phosphonic acid, propylphosphonic acid (PPAc), isopropylphosphonic acid, ethylphosphonic acid (EPAc), butyl phosphonic acid, tert-butyl phosphonic acid, pentyl phosphonic acid, hexyl phosphonic acid, or a combination thereof

### Methods

Also provided herein are methods of preparing semiconducting perovskite films, including perovskite solar cells. These methods can comprise depositing a layer comprising one or more phosphonic acids on a substrate to form a functionalization layer disposed on the substrate; and evaporating one or more precursor materials on the functionalization layer to form an active layer comprising a semiconducting perovskite material disposed on the functionalized layer.

In some embodiments, the substrate comprises an optically transparent material (e.g., a conductive oxide, such as fluorine-doped tin oxide (FTO) or indium tin oxide (ITO)).

Deposition of the one or more phosphonic acids can be performed using conditions effective to produce a functionalization layer having the desired thickness. In some embodiments, the functionalization layer can have a thickness greater than a monolayer. In certain embodiments, the functionalization layer can have a thickness of at least 1 nm.

In some embodiments, the functionalization layer can have a thickness of at least 2 nm (e.g., at least 3 nm, at least 4 nm, at least 5 nm, at least 10 nm, at least 15 nm, at least 20 nm, at least 25 nm, at least 30 nm, at least 40 nm, at least 50 nm, at least 60 nm, at least 70 nm, at least 75 nm, at least 80 nm, at least 90 nm, at least 100 nm, at least 110 nm, at least 115 nm, at least 120 nm, at least 125 nm, at least 130 nm, at least 140 nm, at least 150 nm, at least 160 nm, at least 170 nm, at least 175 nm, at least 180 nm, at least 190 nm, at least 200 nm, at least 210 nm, at least 215 nm, at least 220 nm, at least 225 nm, at least 230 nm, or at least 240 nm).

In some embodiments, the functionalization layer can have a thickness of 250 nm or less (e.g., 240 nm or less, 230 nm or less, 225 nm or less, 220 nm or less, 210 nm or less, 200 nm or less, 190 nm or less, 180 nm or less, 175 nm or less, 170 nm or less, 160 nm or less, 150 nm or less, 140 nm or less, 130 nm or less, 125 nm or less, 120 nm or less, 110 nm or less, 100 nm or less, 90 nm or less, 80 nm or less, 75 nm or less, 70 nm or less, 60 nm or less, 50 nm or less, 40 nm or less, 30 nm or less, 25 nm or less, 20 nm or less, 10 nm or less, or 5 nm or less).

The functionalization layer can have a thickness ranging from any of the minimum values described above to any of the maximum values described above. For example, in some embodiments, the functionalization layer can have a thickness of from 1 nm to 250 nm (e.g., from 1 nm to 200 nm, from 1 nm to 150 nm, from 1 nm to 100 nm, from 1 nm to 50 nm, from 1 nm to 25 nm, from 5 nm to 250 nm, from 5 nm to 200 nm, from 5 nm to 150 nm, from 5 nm to 100 nm, from 5 nm to 50 nm, or from 5 nm to 25 nm).

The one or more phosphonic acids can be deposited on the substrate using a variety of suitable methods. In certain embodiments, the one or more phosphonic acids can be deposited on the substrate using a solution-based deposition technique. Such methods can involve the application of a solution comprising one or more phosphonic acids to a substrate, a subsequent post-treatment step (e.g., drying annealing, or any combination thereof) to form the functionalization layer disposed on the substrate. Spin coating is one effective technique for thin film deposition due to low cost, uniformity, less hazardous, and capability of easy scaling up.

The typical process involves depositing a small amount of a fluid onto the center of a substrate and then spinning the substrate at high speed. Dip coating is another simple, cost effective route with feasibility to scale-up for commercial production. The dip coating process can be divided into three important technical stages, immersion, withdrawal and evaporation. The coating may be subjected to further heat treatment in order to burn out residual compounds and induce crystallization of the one or more phosphonic acids. Spray coating is a promising technique to grow thin film in research and industry to prepare thin and thick films. It is an easy approach to fabricate thin film with uniform distribution at small scale from a few nanometers to micrometers in thickness. Inkjet printing is also a promising technique that can be used to deposit thin films on substrates.

Examples of methods that can be used to apply one or more phosphonic acids on a substrate to form a functionalization layer include casting, doctor blading, screen printing, inkjet printing, pad printing, knife coating, meniscus coating, slot die coating, gravure coating, reverse gravure coating, kiss coating, micro-roll coating, curtain coating, slide coating, spray coating, flexographic printing, offset printing, rotatory screen printing, spin coating or dip coating.

In certain embodiments, depositing the layer comprising one or more phosphonic acids on the substrate comprises spin coating the one or more phosphonic acids, dip coating one or more phosphonic acids, spray coating one or more phosphonic acids, ink jet printing one or more phosphonic acids, or a combination thereof. In particular embodiments, depositing the layer comprising one or more phosphonic acids on the substrate comprises spin coating the one or more phosphonic acids.

The phosphonic acid can comprise a variety of suitable phosphonic acids. In some examples, the phosphonic acid can comprise a phosphonic acid defined by the formula below

R—PO—(OH)₂

where R represents an organic moiety such as aryl (e.g., phenyl), heteroaryl, halogen-substituted aryl, halogen-substituted heteroaryl, alkoxy-substituted aryl (methoxyphenyl, ethoxyphenyl), alkoxy-substituted heteroaryl, cycloalkyl, alkyl, halogen-substituted alkyl, vinyl, allyl, benzyl, aminoalkyl, and hydroxyalkyl. Specific examples of phosphonic acids include methylphosphonic acid, ethylphosphonic acid, n-propylphosphonic acid, isopropylphosphonic acid, n-butylphosphonic acid, isobutylphosphonic acid, t-butylphosphonic acid, n-pentylphosphonic acid, neopentylphosphonic acid, cyclohexylphosphonic acid, benzylphosphonic acid, chloromethylphosphonic acid, dichloromethylphosphonic acid, bromomethylphosphonic acid, dibromomethylphosphonic acid, 2-chloroethylphosphonic acid, 1,2-dichloroethylphosphonic acid, 2-bromoethylphosphonic acid, 1,2-dibromoethylphosphonic acid, 3-chloropropylphosphonic acid, 2,3-dichloropropylphosphonic acid, 3-bromopropylphosphonic acid, 2,3-dibromopropylphosphonic acid, 2-chloro-1-methylethylphosphonic acid, 1,2-dichloro-1-methylethylphosphonic acid, 2-bromo-1-methylethylphosphonic acid, 1,2-dibromo-1-methylethylphosphonic acid, 4-chlorobutylphosphonic acid, 3,4-dichlorobutylphosphonic acid, 4-bromobutylphosphonic acid, 3,4-dibromobutylphosphonic acid, 3-chloro-1-methylpropylphosphonic acid, 2,3-dichloro-1-methylpropylphosphonic acid, 3-bromo-1-methylpropylphosphonic acid, 2,3-dibromo-1-methylphosphonic acid, 1-chloromethylpropylphosphonic acid, 1-chloro-1-chloromethylpropylphosphonic acid, 1-bromomethylpropylphosphonic acid, 1-bromo-1-bromomethylpropylphosphonic acid, 5-chloropentylphosphonic acid, 4,5-dichloropentylphosphonic acid, 5-bromopentylphosphonic acid, 4,5-dibromopentylphosphonic acid, 1-hydroxymethylphosphonic acid, 2-hydroxyethylphosphonic acid, 3-hydroxypropylphosphonic acid, 4-hydroxybutylphosphonic acid, 5-hydroxypentylphosphonic acid, 1-aminomethylphosphonic acid, 2-aminoethylphosphonic acid, 3-aminopropylphosphonic acid, 4-aminobutylphosphonic acid, 5-aminopentylphosphonic acid, methylthiomethylphosphonic acid, methylthioethylphosphonic acid, methylthiopropylphosphonic acid, methylthiobutylphosphonic acid, ethylthiomethylphosphonic acid, ethylthioethylphosphonic acid, ethylthiopropylphosphonic acid, propylthiomethylphosphonic acid, propylthioethylphosphonic acid, butylthiomethylphosphonic acid, phenylphosphonic acid, 4-chlorophenylphosphonic acid, 3,4-dichlorophenylphosphonic acid, 3,5-dichlorophenylphosphonic acid, 4-bromophenylphosphonic acid, 3,4-dibromophenylphosphonic acid, 3,5-dibromophenylphosphonic acid, 4-methoxyphenylphosphonic acid, 3,4-dimethoxyphenylphosphonic acid, 1-naphthylphosphonic acid, 2-naphthylphosphonic acid, benzylphosphonic acid, 4-bromophenylmethylphosphonic acid, 3,4-dibromophenylmethylphosphonic acid, 3,5-dibromophenylmethylphosphonic acid, 2-phenylethylphosphonic acid, 2-(4-bromophenyl)ethylphosphonic acid, 2-(3,4-dibromophenyl)ethylphosphonic acid, 2-(3,5-dibromophenyl)ethylphosphonic acid, 3-phenylpropylphosphonic acid, 3-(4-bromophenyl)propylphosphonic acid, 3-(3,4-dibromophenyl)propylphosphonic acid, 3-(3,5-dibromophenyl)propylphosphonic acid, 4-phenylbutylphosphonic acid, 4-(4-bromophenyl)butylphosphonic acid, 4-(3,4-dibromophenyl)butylphosphonic acid, 4-(3,5-dibromophenyl)butylphosphonic acid, 2-pyridylphosphonic acid, 3-pyridylphosphonic acid, 4-pyridylphosphonic acid, 1-pyrrolidinomethylphosphonic acid, 1-pyrrolidinoethylphosphonic acid, 1-pyrrolidinopropylphosphonic acid, 1-pyrrolidinobutylphosphonic acid, pyrrole-1-phosphonic acid, pyrrole-2-phosphonic acid, pyrrole-3-phosphonic acid, thiophene-2-phosphonic acid, thiophene-3-phosphonic acid, dithiane-2-phosphonic acid, trithiane-2-phosphonic acid, furan-2-phosphonic acid, furan-3-phosphonic acid, vinylphosphdnic acid, allylphosphonic acid, and 2-norbornylphosphonic acid.

In some embodiments, the one or more phosphonic acids comprise methyl phosphonic acid, propylphosphonic acid (PPAc), ethylphosphonic acid (EPAc), 3-bromopropyl phosphonic acid (3BrPPAc), 3-phosphonopropionic acid (3PPAc), butyl phosphonic acid, pentyl phosphonic acid, hexyl phosphonic acid, or a combination thereof.

In certain embodiments, the one or more phosphonic acids comprise a phosphonic acid defined by the formula below

R—PO—(OH)₂

where R represents a C₁-C₈ alkyl group.

In certain embodiments, the one or more phosphonic acids comprise methyl phosphonic acid, propylphosphonic acid (PPAc), isopropylphosphonic acid, ethylphosphonic acid (EPAc), butyl phosphonic acid, tert-butyl phosphonic acid, pentyl phosphonic acid, hexyl phosphonic acid, or a combination thereof.

In some embodiments, the one or more precursor materials comprises an organic component and an inorganic component.

In some embodiments, the organic component comprises an organic monovalent defined by the formula [R¹R²N—CH═NR³R⁴]⁺:

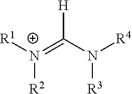

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group. In certain embodiments, the organic component comprises a formamidinium salt, such as formamidinium iodide, or a methylammonium salt, such as methylammonium iodide.

In some embodiments, the inorganic component comprises Pb, Sn, Ge, Si, Ti, Bi, In, or a combination thereof. In certain embodiments, the inorganic component comprises a lead halide, such as PbI₂.

In some embodiments, the evaporating one or more precursor materials on the functionalization layer comprises simultaneous vapor phase deposition of the organic component and the inorganic component.

In some embodiments, the organic component and the inorganic component are each deposited at a deposition rate of from 0.2 Å/second to 0.8 Å/second.

In some embodiments, the evaporation is continued until the active layer has a thickness of from 100 nm to 100 μm (e.g., from 100 nm to 50 μm, from 100 nm to 10 μm, from 100 nm to 1 μm, from 200 nm to 100 μm, from 200 nm to 50 μm, from 200 nm to 10 μm, from 200 nm to 1 μm, from 500 nm to 100 μm, from 500 nm to 50 μm, from 500 nm to 10 μm, or from 500 nm to 1 μm).

In some embodiments, the semiconducting perovskite material exhibits a substantially cubic phase.

In some embodiments, the semiconducting perovskite material is substantially free of a δ-phase.

In some embodiments, the method further comprises rotating the substrate during evaporation of the one or more precursor materials on the functionalization layer to enhance uniformity of the active layer.

In some embodiments, the method further comprises coating the substrate with an electron transport layer (ETL) or a hole transport layer (HTL) prior to depositing the layer comprising the one or more phosphonic acids on the substrate. In certain embodiments, the method further comprises coating the substrate with the ETL, and the ETL comprises tin oxide, titanium oxide, zinc oxide, a fullerene-based material, or a combination thereof. In other embodiments, the method further comprises coating the substrate with the HTL, and the HTL comprises nickel oxide, vanadium oxide, spiro OMeTAD, poly[bis(4-phenyl)(2,4,6-trimethylphenyl)amine (PTAA), phosphonic acid based molecules such as ([2-(9H-carbazol-9-yl)ethyl]phosphonic acid (2PACz), or a combination thereof.

### Example Embodiments

Described herein are embodiments including the particular embodiments described below.
Embodiment 1: A composition comprising:
   a substrate;
   a functionalization layer disposed on the substrate, wherein the functionalization layer comprises one or more phosphonic acids; and
   an active layer comprising a semiconducting perovskite material disposed on the functionalized layer.
Embodiment 2. The composition of embodiment 1, wherein the functionalization layer has a thickness greater than a monolayer.
Embodiment 3. The composition of any one of embodiments 1-2, wherein the functionalization layer has a thickness of from 1 nm to 250 nm.
Embodiment 4. The composition of any one of embodiments 1-3, wherein the substrate comprises an optically transparent material.
Embodiment 5. The composition of any one of embodiments 1-4, wherein the substrate comprises a conductive oxide, such as fluorine-doped tin oxide (FTO) or indium tin oxide (ITO).
Embodiment 6. The composition of any one of embodiments 1-5, wherein the semiconducting perovskite material comprises an organometal halide perovskite material.
Embodiment 7. The composition of embodiment 6, wherein the organometal halide perovskite material is defined by a general formula ABX₃, where A comprises at least one organic monovalent cation, B comprises at least one divalent inorganic cation, and X comprises at least one halide ion.
Embodiment 8. The composition of embodiment 7, wherein the organic monovalent cation comprises a primary, secondary or tertiary ammonium cation [HNR¹R²R³]⁺, wherein each of R¹, R² and R³ may be the same or different and is selected from hydrogen, an unsubstituted or substituted C₁-C₂₀ alkyl group and an unsubstituted or substituted C₅-C₁₈ aryl group.
Embodiment 9. The composition of embodiment 7, wherein the organic monovalent cation comprises is defined by the formula [R¹R²N—CH═NR³R⁴]⁺:

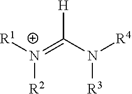

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.
Embodiment 10. The composition of embodiment 7, wherein the organic monovalent cation comprises is defined by the formula (R¹R²N)(R³R⁴N)C═NR⁵R⁶:

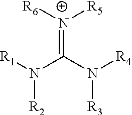

wherein each of R¹R², R³, R⁵ and R⁶ may be the same or different and is selected from hydrogen, an unsubstituted or substituted C₁-C₂₀ alkyl group and an unsubstituted or substituted C₅-C₁₈ aryl group.
Embodiment 11. The composition of any one of embodiments 7-10, wherein the organic monovalent cation comprises a formamidinium cation.
Embodiment 12. The composition of any one of embodiments 7-11, wherein A further comprises a monovalent metal cation.
Embodiment 13. The composition of embodiment 12, wherein the monovalent cation comprises an alkali metal cation.
Embodiment 14. The composition of any one of embodiments 7-13, wherein A further comprises one or more of Cs⁺, Rb⁺, Cu⁺, Pd⁺, Pt⁺, Ag⁺, Au⁺, Rh, and Ru.
Embodiment 15. The composition of any one of embodiments 7-14, wherein divalent cation B comprises a divalent metal cation.
Embodiment 16. The composition of embodiment 15, wherein the divalent metal cation comprises Sn²⁺, Pb²⁺, Ge²⁺, or any combination thereof.
Embodiment 17. The composition of any one of embodiments 7-16, wherein X is chloride, bromide, iodide, fluoride, or a combination thereof.
Embodiment 18. The composition of any one of embodiments 7-17, wherein X is bromide, iodide, or a combination thereof.
Embodiment 19. The composition of embodiment 6, wherein the organometal halide perovskite material has an Aᵢ₋₁A′ᵢBX₃ structure, wherein:
   A and A′ are each a monovalent cation as claimed in any one of claims 8-14, where A and A′ are different, and wherein at least one of A and A′ is an organic monovalent cation;
   B is a divalent cation as claimed in any one of claims 15-16;
   X is a halide anion as claimed in any one of claims 17-18; and
   i is between 0 and 1.
Embodiment 20. The composition of embodiment 6, wherein the organometal halide perovskite material has an ABX₃₋ₖX′ₖ structure, wherein:
   A is an organic monovalent cation as claimed in any one of claims 8-14;
   B is a divalent cation as claimed in any one of claims 15-16;
   X and X′ are each a halide anion as claimed in any one of claims 17-18, where X and X′ are different; and
   k is between 0 and 3.
Embodiment 21. The composition of embodiment 6, wherein the organometal halide perovskite material has an AB₁₋ᵢB′ⱼX₃ structure, wherein:
   A is an organic monovalent cation as claimed in any one of claims 8-14;
   B and B′ are each a divalent cation as claimed in any one of claims 15-16, wherein B and B′ are different;
   X is a halide anion as claimed in any one of claims 17-18; and
   j is between 0 and 1.
Embodiment 22. The composition of embodiment 6, wherein the organometal halide perovskite material has an Aᵢ₋₁A′ᵢB₁₋ⱼB′ⱼX₃₋ₖX′ₖ structure, wherein:
   A and A′ are each a monovalent cation as claimed in any one of claims 8-14, where A and A′ are different, and wherein at least one of A and A′ is an organic monovalent cation;
   B and B′ are each a divalent cation as claimed in any one of claims 15-16, wherein B and B′ are different;
   X and X′ are each a halide anion as claimed in any one of claims 17-18, where X and X′ are different; and
   where i is between 0 and 1, j is between 0 and 1, and k is between 0 and 3.
Embodiment 23. The composition of any one of embodiments 1-22, wherein the semiconducting perovskite material exhibits a substantially cubic phase.
Embodiment 24. The composition of any one of embodiments 1-23, wherein the semiconducting perovskite material is substantially free of a δ-phase.
Embodiment 25. The composition of any one of embodiments 1-24, wherein the one or more phosphonic acids comprise methyl phosphonic acid, propylphosphonic acid (PPAc), ethylphosphonic acid (EPAc), 3-bromopropyl phosphonic acid (3BrPPAc), 3-phosphonopropionic acid (3PPAc), butyl phosphonic acid, pentyl phosphonic acid, hexyl phosphonic acid, or a combination thereof.
Embodiment 26. The composition of any one of embodiments 1-25, wherein the substrate is coated with an electron transport layer (ETL).
Embodiment 27. The composition of embodiment 26, wherein the ETL comprises tin oxide, titanium oxide, zinc oxide, a fullerene-based material, or a combination thereof.
Embodiment 28. The composition of any one of embodiments 1-25, wherein the substrate is coated with a hole transport layer (HTL).
Embodiment 29. The composition of embodiment 28, wherein the HTL comprises nickel oxide, vanadium oxide, spiro OMeTAD, poly[bis(4-phenyl)(2,4,6-trimethylphenyl)amine (PTAA), phosphonic acid based molecules such as ([2-(9H-carbazol-9-yl)ethyl]phosphonic acid (2PACz), or a combination thereof.
Embodiment 30. A method comprising:
   depositing a layer comprising one or more phosphonic acids on a substrate to form a functionalization layer disposed on the substrate; and
   evaporating one or more precursor materials on the functionalization layer to form an active layer comprising a semiconducting perovskite material disposed on the functionalized layer.
Embodiment 31. The method of embodiment 30, wherein the functionalization later has a thickness greater than a monolayer.
Embodiment 32. The method of any one of embodiments 30-31, wherein the functionalization layer has a thickness of from 1 nm to 250 nm.
Embodiment 33. The method of any one of embodiments 30-32, wherein depositing the layer comprising one or more phosphonic acids on the substrate comprises spin coating the one or more phosphonic acids, dip coating one or more phosphonic acids, spray coating one or more phosphonic acids, ink jet printing one or more phosphonic acids, or a combination thereof.
Embodiment 34. The method of any one of embodiments 30-33, wherein the one or more phosphonic acids comprise a phosphonic acid defined by the formula below

R—PO—(OH)₂

where R represents a C₁-C₈ alkyl group.
Embodiment 35. The method of any one of embodiments 30-34, wherein the one or more phosphonic acids comprise methyl phosphonic acid, propylphosphonic acid (PPAc), isopropylphosphonic acid, ethylphosphonic acid (EPAc), butyl phosphonic acid, tert-butyl phosphonic acid, pentyl phosphonic acid, hexyl phosphonic acid, or a combination thereof.
Embodiment 36. The method of any one of embodiments 30-35, wherein the one or more precursor materials comprises an organic component and an inorganic component.
Embodiment 37. The method of embodiments 36, wherein the organic component comprises an organic monovalent defined by the formula [R¹R²N—CH═NR³R⁴]⁺:

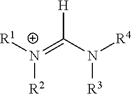

wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.
Embodiment 38. The method of embodiment 36, wherein the organic component comprises a formamidinium salt, such as formamidinium iodide, or a methylammonium salt, such as methylammonium iodide.
Embodiment 39. The method of any one or embodiments 36-38, wherein the inorganic component comprises Pb, Sn, Ge, Si, Ti, Bi, In, or a combination thereof.
Embodiment 40. The method of any one of embodiments 36-39, wherein the inorganic component comprises a lead halide, such as PbI₂.
Embodiment 41. The method of any one of embodiments 36-40, wherein evaporating one or more precursor materials on the functionalization layer comprises simultaneous vapor phase deposition of the organic component and the inorganic component.
Embodiment 42. The method of any one of embodiments 36-41, wherein the organic component and the inorganic component are each deposited at a deposition rate of from 0.2 Å/second to 0.8 Å/second.
Embodiment 43. The method of any one of embodiments 30-42, wherein evaporation is continued until the active layer has a thickness of from 100 nm to 100 m.
Embodiment 44. The method of any one of embodiments 30-43, wherein the semiconducting perovskite material exhibits a substantially cubic phase.
Embodiment 45. The method of any one of embodiments 30-44, wherein the semiconducting perovskite material is substantially free of a δ-phase.
Embodiment 46. The method of any one of embodiments 30-45, further comprising rotating the substrate during evaporation of the one or more precursor materials on the functionalization layer to enhance uniformity of the active layer.
Embodiment 47. The method of any one of embodiments 30-46, further comprising coating the substrate with an electron transport layer (ETL) or a hole transport layer (HTL) prior to depositing the layer comprising the one or more phosphonic acids on the substrate.
Embodiment 48. The method of claim 47, wherein the method further comprises coating the substrate with the ETL, wherein the ETL comprises tin oxide, titanium oxide, zinc oxide, a fullerene-based material, or a combination thereof, or
   wherein the method further comprises coating the substrate with the HTL, and the HTL comprises nickel oxide, vanadium oxide, spiro OMeTAD, poly[bis(4-phenyl)(2,4,6-trimethylphenyl)amine (PTAA), phosphonic acid based molecules such as ([2-(9H-carbazol-9-yl)ethyl]phosphonic acid (2PACz), or a combination thereof.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary and are not intended to limit the scope of the disclosure. Unless indicated otherwise, parts are parts by weight, temperature is in ° C. or is at ambient temperature, and pressure is at or near atmospheric.

### Example 1. Tailoring Interface Energies via Phosphonic Acids to Grow and Stabilize Cubic FAPbI₃ Deposited by Thermal Evaporation

### Overview

Coevaporation of formamidinium lead iodide (FAPbI₃) is a promising route for the fabrication of highly efficient and scalable optoelectronic devices, such as perovskite solar cells. However, it poses experimental challenges in achieving stoichiometric FAPbI₃ films with a cubic structure (α-FAPbI₃). In this Example, we show that undesired hexagonal phases of both PbI₂ and FAPbI₃ form during thermal evaporation, including the well-known 2H-FAPbI₃, which are detrimental for optoelectronic performance. We demonstrate the growth of α-FAPbI₃ at room temperature via thermal evaporation by depositing phosphonic acids (PAc) on substrates and subsequently coevaporating PbI₂ and formamidinium iodide. We use density-functional theory to develop a theoretical model to understand the relative growth energetics of the α and 2H phases of FAPbI₃ for different molecular interactions. Experiments and theory show that the presence of PAc molecules stabilizes the formation of α-FAPbI₃ in thin films when excess molecules are available to migrate during growth. This migration of molecules facilitates the continued presence of adsorbed organic precursors at the free surface throughout the evaporation, which lowers the growth energy of the α-FAPbI₃ phase. Our theoretical analyses of PAc molecule-molecule interactions show that ligands can form hydrogen bonding to reduce the migration rate of the molecules through the deposited film, limiting the effects on the crystal structure stabilization. Our results also show that the phase stabilization with molecules that migrate is long-lasting and resistant to moist air. These findings enable reliable formation and processing of α-FAPbI₃ films via vapor deposition.

### Results and Discussion

Many strategies to foster the formation of α-FAPbI₃ at ambient conditions have been explored. Alloying FAPbI₃ with Cs⁺ and MA⁺ can be an effective way to favor the α phase formation, via both solution and evaporation. However, it has been shown that MA⁺ causes instabilities in solar cells, mainly due to the fragmentation of MA molecules into H, CH₂, CH₃, CH₄, NH₂, NH₃, and CH₃NH₂ under thermal stress. Moreover, hydrogen migration has also been linked to the formation of defects that affect the device performance. Likewise, Cs⁺ can migrate and segregate, leading to the formation of CsPbI₃ nonperovskite phases.

Research on thermal evaporation of MHPs has shown that the substrate plays a crucial role in the growth mechanism of the MHP layer. Studies on MAPbI₃ demonstrate that the thickness of the deposited layer is dependent on the substrate chemistry, with the sticking factor of MAI being more strongly affected by the substrate. Likewise, α-FAPbI₃ grows at room temperature when both an excess of FAI is present and when the substrate is treated with [2-(3,6-dimethoxy-9H-carbazol-9-yl)ethyl]phosphonic acid (MeO-2PACz). This effect is also beneficial in the evaporation of Cs_{0.13}FA_{0.87}Pb(I_{0.95}Cl_{0.05})₃, where the presence of phosphonic acids (and presumably of Cs) increases the activation energy for the transition from the cubic to the hexagonal phase. However, the influence of the phosphonic acid molecules beyond the interface and how this relates to the formation of the α-FAPbI₃ remains unexplored.

In this Example, we deposit PAc molecules on FTO substrates to investigate the role of surface chemistry on the phase purity and composition of coevaporated FAPbI₃ films. To understand the growth mechanisms of the α phase, we select a range of PAc molecules with different additional moieties that can interact both with the MHP and with one another in varying degrees. These molecules are deposited by spin coating on the substrates where FAPbI₃ precursors are thermally evaporated. Performing X-ray photoelectron spectroscopy (XPS), we show that FA⁺-deficient films are formed on untreated substrates, leading to the formation of the hexagonal phases, including the 6-FAPbI₃ phase. Interestingly, when the surface is treated with some PAc molecules, we measure a higher incorporation of the organic precursors into the film, and the α-FAPbI₃ is induced as the dominant crystalline phase. We performed density functional theory (DFT) calculations to compare the stability of thin films of a and 6 FAPbI₃ perovskites on the fluorine-doped tin oxide (FTO) substrate in the presence and absence of a PAc molecule.

These calculations allow us to develop a theoretical model that relates the growth energy to the grown thickness for each MHP phase, explaining how surface treatments with PAc molecules can help foster the growth of α-FAPbI₃. We further calculate the binding energies (BEs) between the substrate and the PAc as well as between the PAc molecules. This allows us to understand how likely it is for PAc molecules to migrate through the perovskite layer if deposited in amounts exceeding that required to form a monolayer on the substrate. Our simulations and experiments reveal that the migration of PAc molecules through the MHP film promotes the growth of α-FAPbI₃. This process is driven by a consistently high sorption rate of FAI throughout the entire evaporation process and by the reduction of the growth energy of α-FAPbI₃ compared to the δ phase in the presence of PAc molecules. We propose that phosphonic acids with weaker ligand-ligand binding, such as propylphosphonic acid (PPAc), are more likely to migrate and thus contribute to the growth of α-FAPbI₃ films as they are deposited layer by layer in thermal evaporation.

### Results and Discussion

### Thermal Coevaporation of FAPbI₃ Substrates.

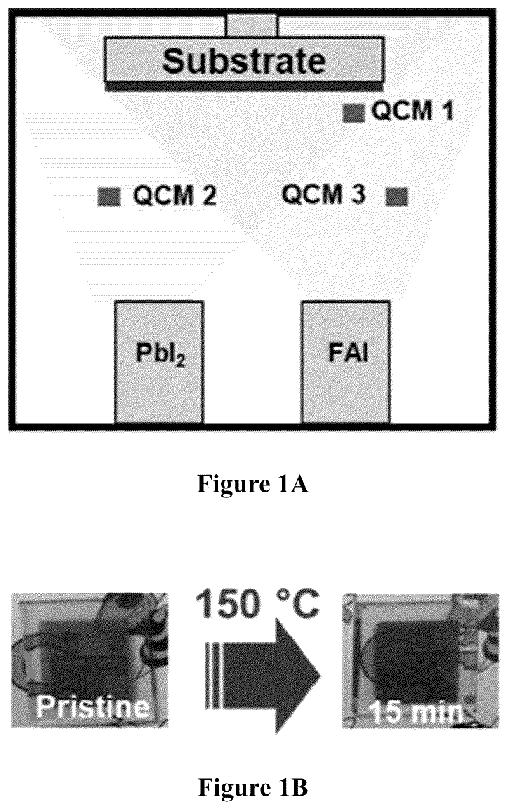

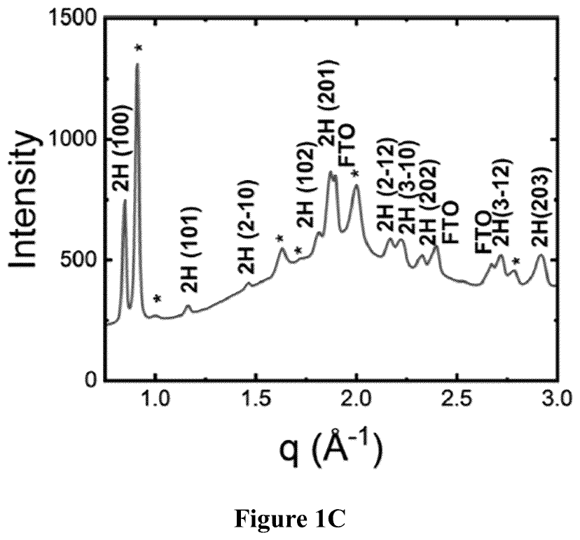

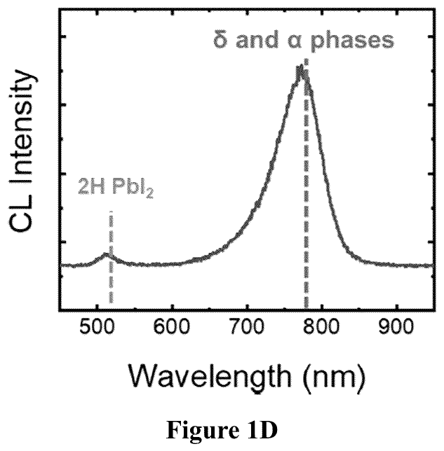

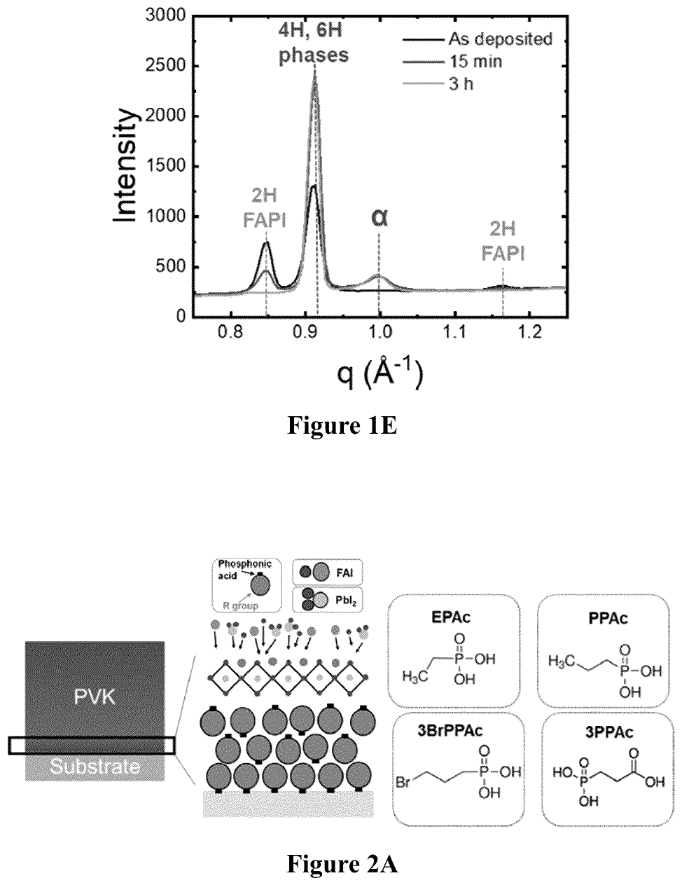

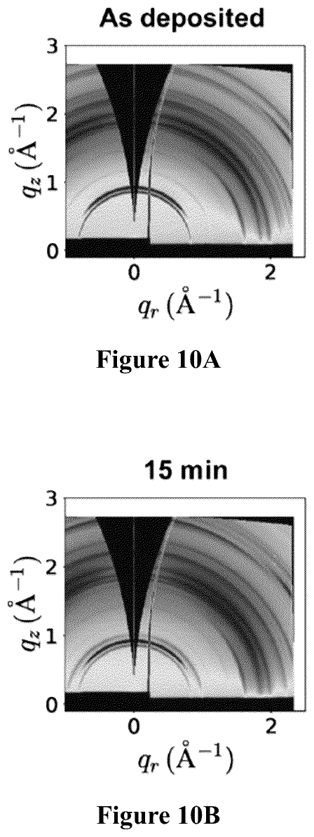

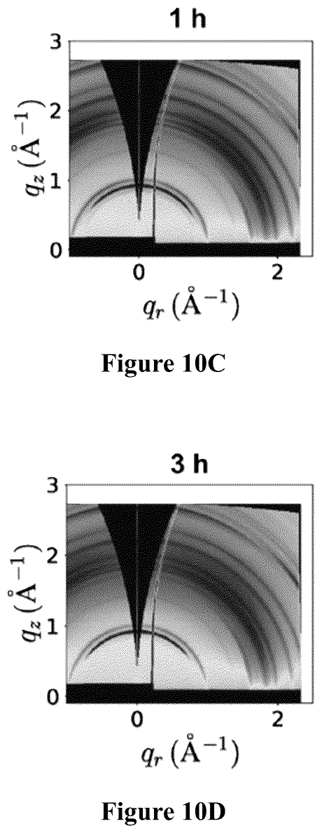

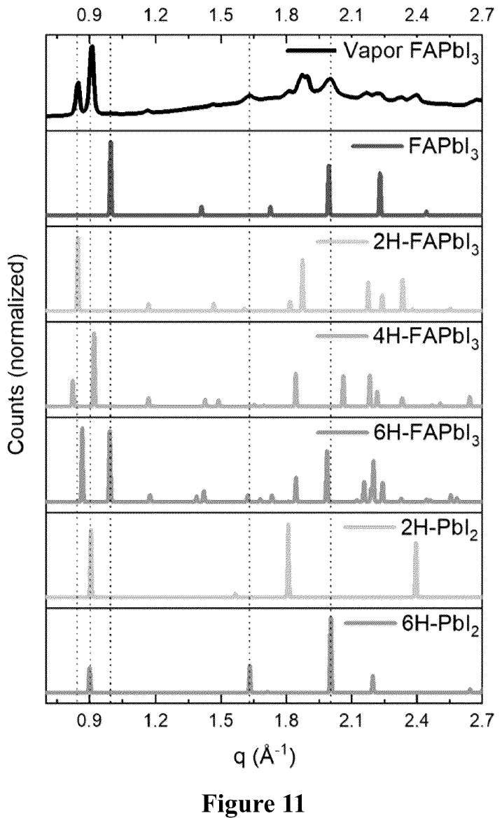

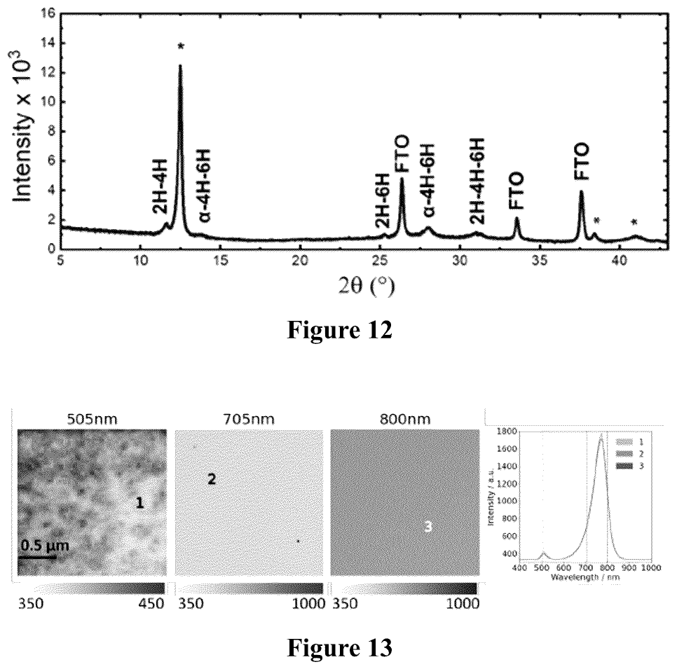

This Example uses coevaporation of PbI₂ and FAI to deposit FAPbI₃ films, as shown in FIG. 1A. Three QCMs, denoted as QCM 1, QCM 2, and QCM 3 in FIG. 1A, are used to monitor the total thickness of the deposited layer at the substrate, to control the deposition rate of PbI₂, and that of FAI, respectively. To ensure the appropriate ratio between the deposition rates of PbI₂ and FAI, the QCMs are calibrated as described below. Upon deposition of FAPbI₃, the deposited film exhibits a yellow/light brown color, suggesting the presence of large amounts of hexagonal phases (FIG. 1B). To identify the crystalline phases formed in the deposited film, we conducted grazing incidence wide-angle X-ray scattering (GIWAXS) of the FAPbI₃ film deposited on FTO (FIG. 1C). The complete 2D GIWAXS pattern of the film is reported in FIGS. 10A-10D, while in FIG. 1C, we show the circular integration of the pattern, which offers easier identification of the peak positions. The diffraction pattern reveals a characteristic peak of the 6-FAPbI₃ phase (predominant peak expected at q=0.84 Å⁻¹) and almost complete absence of crystalline α-FAPbI₃ (predominant peak expected at q=0.99 Å⁻¹). Notably, the most intense diffraction peak is at q=0.91 Å⁻¹, matching with the diffraction expected from the 2H phase of PbI₂. However, two peaks at q=1.63 Å⁻¹ and q=1.73 Å⁻¹ are also present in FIG. 1C and cannot be attributed to the 2H phase of PbI₂, to the α-FAPbI₃, or the 6-FAPbI₃. Although these peaks are close to the diffraction peaks of the 4H and 6H phases for FAPbI₃ (FIG. 11), the peaks match with those expected from the 6H phase of PbI₂, suggesting that this phase is formed when MHP thin films are deposited via vapor. To ensure that the phases observed in GIWAXS represent the as-deposited films and are not a consequence of sample degradation during transportation to the beamline facility, we conducted X-ray diffraction (XRD) of a thin film measured immediately after deposition (FIG. 12), and the phases observed are consistent with those detected with GIWAXS.

To corroborate our understanding of the secondary phases present in the film, we measured cathodoluminescence (CL), as shown in FIG. 1D. CL detects the radiation emitted by the sample upon excitation with an electron beam. This technique proves useful for detecting and mapping distinct phases within the sample, as the wavelength of the emission depends on the bandgap of the material. The FAI-PbI₂ coevaporated samples show homogeneous distribution of the CL map (FIG. 13). The spectra exhibit a weak emission peak centered at a wavelength of 505 nm, matching the emission of 2H PbI₂. A broader and more intense peak is observed centered at an emission wavelength of 790 nm, blue-shifted with respect to the emission peak of pure α-FAPbI₃ (FIG. 1C). This peak is also asymmetric, suggesting the presence of more than one phase. Such shift and broadening of the emission has also been observed in the PL data of MHP films and can be attributed to hexagonal phases of FAPbI₃ or possibly from the 6H of PbI₂. In addition, the observed blue shift in the emission peak is consistent with theoretical predictions of the band gap for the hexagonal polytypes. A mixture of hexagonal polytypes is therefore likely to be present in the film.

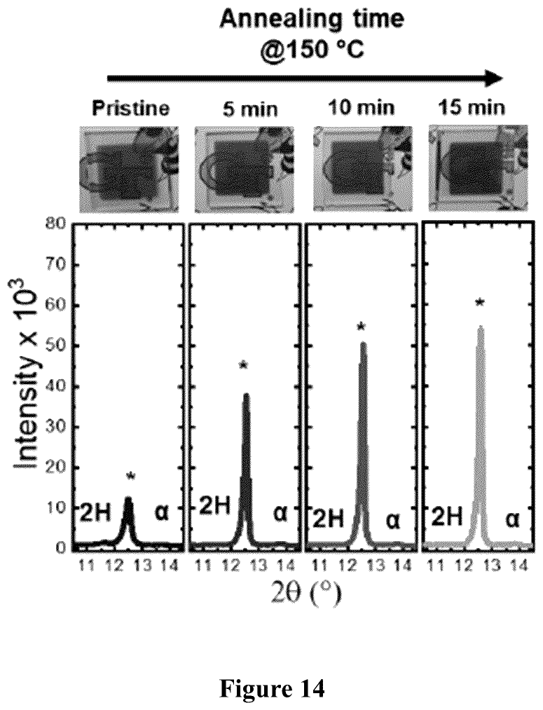

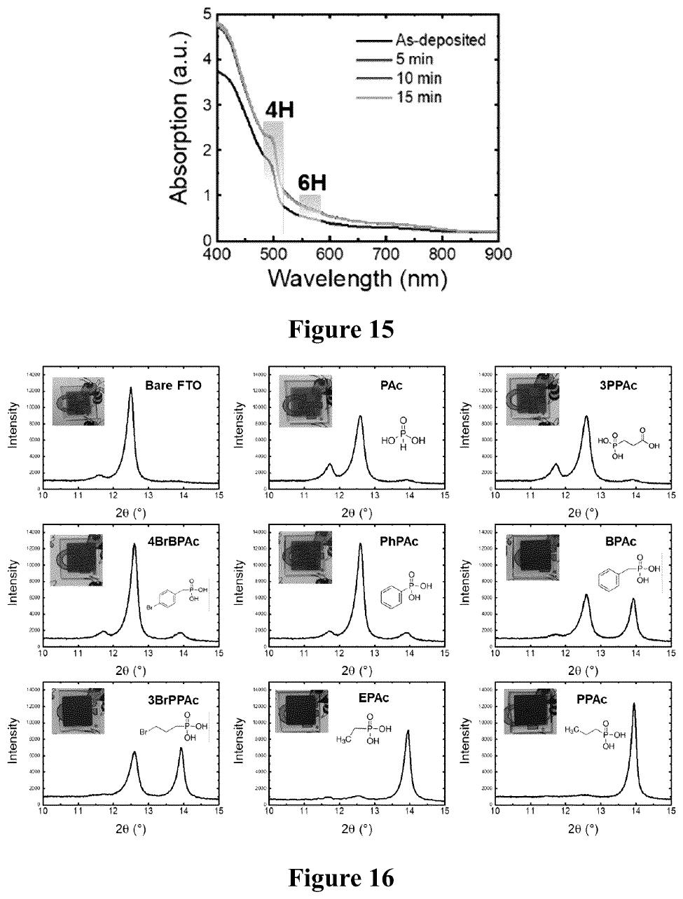

A common approach for converting 6-FAPbI₃ films into the α-FAPbI₃ phase in solution-processed films is to thermally anneal them at 150° C., the temperature at which the α phase is thermodynamically more stable compared to its hexagonal counterparts. FIG. 1E shows the circularly integrated GIWAXS patterns (FIG. 14 shows the XRD data) as a function of annealing time at 150° C. Annealing leads to the decrease of the 6-FAPbI₃ (q=0.84 Å⁻¹, 2θ=11.65°) and to the emergence of a small peak that belongs to the α-FAPbI₃ (q=0.99 Å⁻¹, 2θ=13.9°). Moreover, the peak at q=0.91 Å⁻¹ (2θ=12.5°, which belongs to the hexagonal polymorphs) increases in intensity. In solution processing, this annealing approach has been reported to suppress all nonperovskite phases and promote the growth of the α-FAPbI₃ (q=0.99 Å⁻¹), which is not the case for our evaporated films. Furthermore, annealing of the films leads to an increase in the intensity of the absorption shoulders at 500 and 560 nm observed by UV-vis spectroscopy in FIG. 15, which are typically related to the 6-FAPbI₃ phase.

### Thermal Coevaporation of FAPbI₃ on PAc-Treated Substrates.

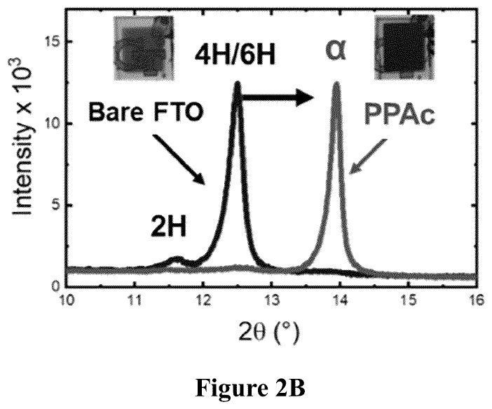

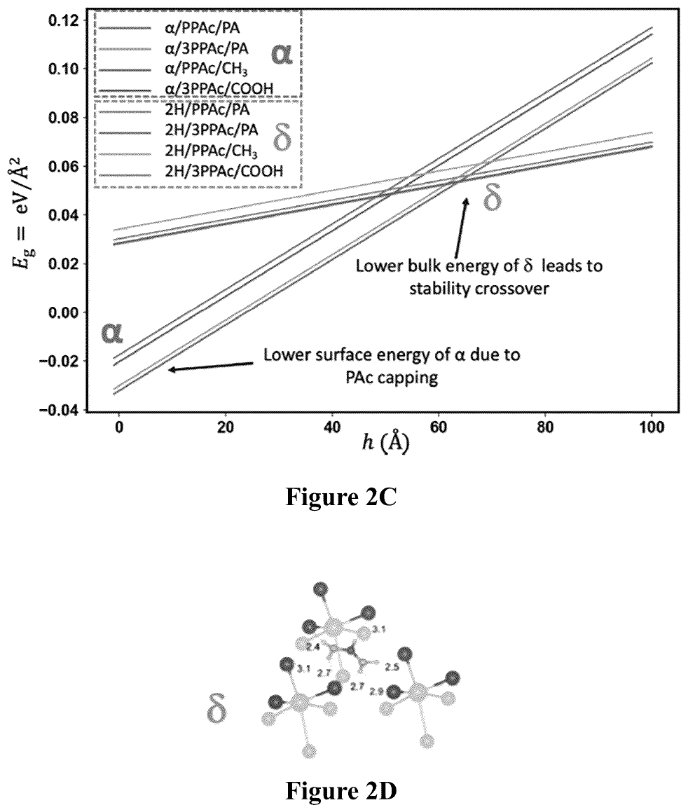

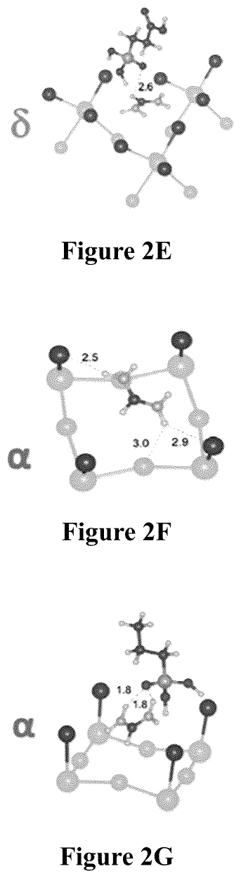

To promote the growth of α-FAPbI₃ without the need for post-annealing steps or compositional engineering of the MHP, we deposited the FTO substrate with Pac molecules, as shown in the schematic provided in FIG. 2A. This treatment aims to stabilize the α-FAPbI₃ by creating molecular interactions (e.g., hydrogen bonds) between the PAc molecule and the polar MHP precursors during evaporation. We selected a variety of PAc molecules with additional moieties capable of interacting with both the MHP precursor and with each other to varying degrees. We considered PAc molecules with aliphatic moieties such as ethyl-phosphonic acid (EPAc) and PPAc, PAc molecules with halide moieties such as 3-bromopropylphosphonic acid (3BrPPAc), with moieties that can form hydrogen bonding such as 3-phosphonopropionic acid (3PPAc), and with moieties containing π orbitals such as phenyl phosphonic acid (PhPAc). FIG. 16 shows the XRD of the MIP films deposited on substrates treated with these molecules. We observed that PAc molecules with ligands that interact weakly with each other, such as those in PPAc and EPAc, are particularly effective in promoting the growth of α-FAPbI₃. PPAc and EPAc are the only molecules we studied as surface modifiers that lead to the formation of mostly α-FAPbI₃, with a peak at 2θ=13.95°. In contrast, molecules with ligands that tend to interact more strongly with each other, such as halogens, oxygens, and phenyl rings, lead to the formation of films containing both α and hexagonal phases of PbI₂ and FAPbI₃. For instance, the use of 3BrPPAc induces a mixture of α- and hexagonal polytypes of PbI₂ and FAPbI₃, while 3PPAc results in films composed solely of hexagonal polytypes of PbI₂ and FAPbI₃. These results suggest that the characteristics of the ligands, and not just the PAc group, play a role in facilitating the growth of α-FAPbI₃.

TABLE 1
FAPbI₃ Bulk Formation Energy (E_{form}), Bare
Separation Energy (Eₛₑₚ), and Capping Energy (E_{cap})
Calculated per Eq. 1-3, Corresponding to FAI-and PbI₂-Terminated
Slab Models of α- and 2H-FAPbI₃. The energy of growing
FAPbI₃ (E_{g}) at a thickness of h (FIG. 2C and
FIG. 9) composed of these terms can be obtained via Eq. 4.

| capping molecule | PPA-capped | | 3PPA-capped | |
|---|---|---|---|---|
| mode, grown | via PA α, | via CH₃ α, | via PA α, | via COOH α, |
| phase | 2H | 2H | 2H | 2H |

PbI₂ Termination

| | | | | |
|---|---|---|---|---|
| E_{form} | 1.34, | 1.34, | 1.34, | 1.34, |
| (meV/Å³) | 0.39 | 0.39 | 0.39 | 0.39 |
| Eₛₑₚ | 2.21, | 2.21, | 2.21, | 2.21, |
| (meV/Å²) | 39.18 | 39.18 | 39.18 | 39.18 |
| E_{cap} | −36.98, | −13.74, | −36.37, | −26.11, |
| (meV/Å²) | −13.02 | −4.41 | −11.90 | −7.20 |

FAI Termination

| | | | | |
|---|---|---|---|---|
| E_{form} | 1.34, | 1.34, | 1.34, | 1.34, |
| (meV/Å³) | 0.39 | 0.39 | 0.39 | 0.39 |
| Eₛₑₚ | 2.21, | 2.21, | 2.21, | 2.21, |
| (meV/Å²) | 39,18 | 39.18 | 39.18 | 39.18 |
| E_{cap} | −34.40, | −19.74, | −32,33, | −22.59, |
| (meV/Å²) | −13.08 | −5.00 | −10.69 | −8.97 |

$${E}_{form} + {E}_{FAPI} - {E}_{FAI} - {E}_{PbI 2} \qquad ( Eq . 1 )$$

$${E}_{sep} = ( {E}_{slab} - {E}_{bulk} ) / A \qquad ( Eq . 2 )$$

$$E cap = ( E slab - PAc - E slab - E PAc ) / A \qquad ( Eq . 3 )$$

$${E}_{g} = {E}_{form} \cdot h + {E}_{sep} + {E}_{cap} \qquad ( Eq . 4 )$$

$${BE}_{PAc} = {E}_{FTO - PAc} - {E}_{PAc} {-}_{\\} {E}_{FTO} \qquad ( Eq . 5 )$$

$${BE}_{PAc - PAc} = {E}_{( FTO - PAc - PAc )} - {E}_{( FTO - PAc )} - EPAc \qquad ( Eq . 6 )$$

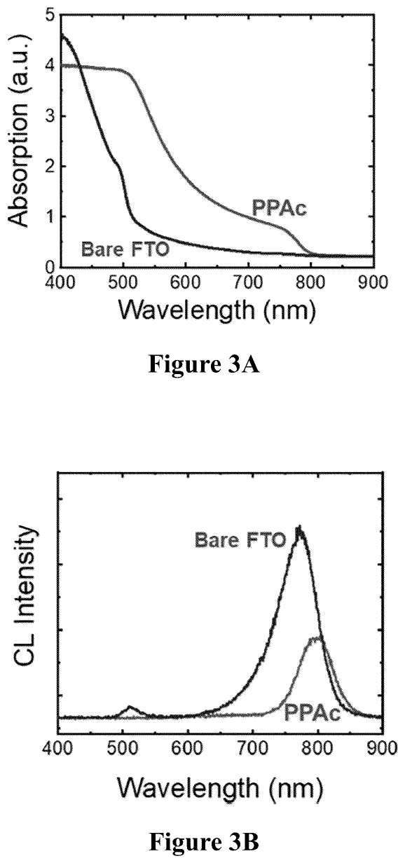

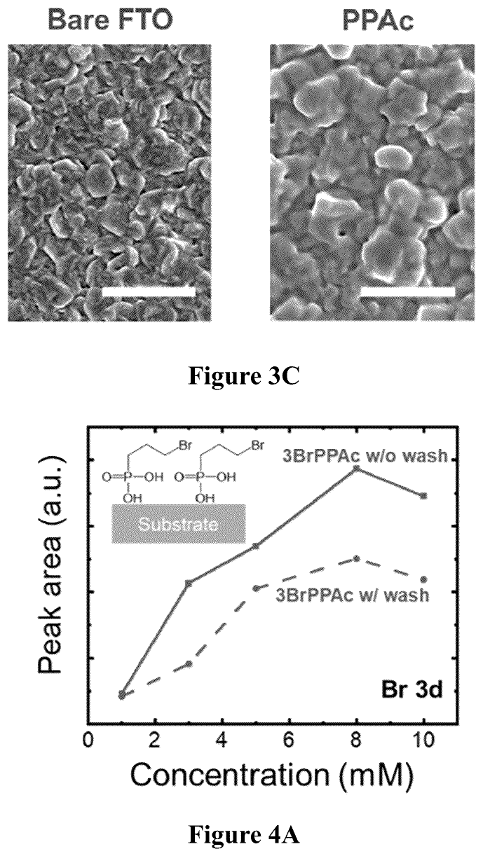

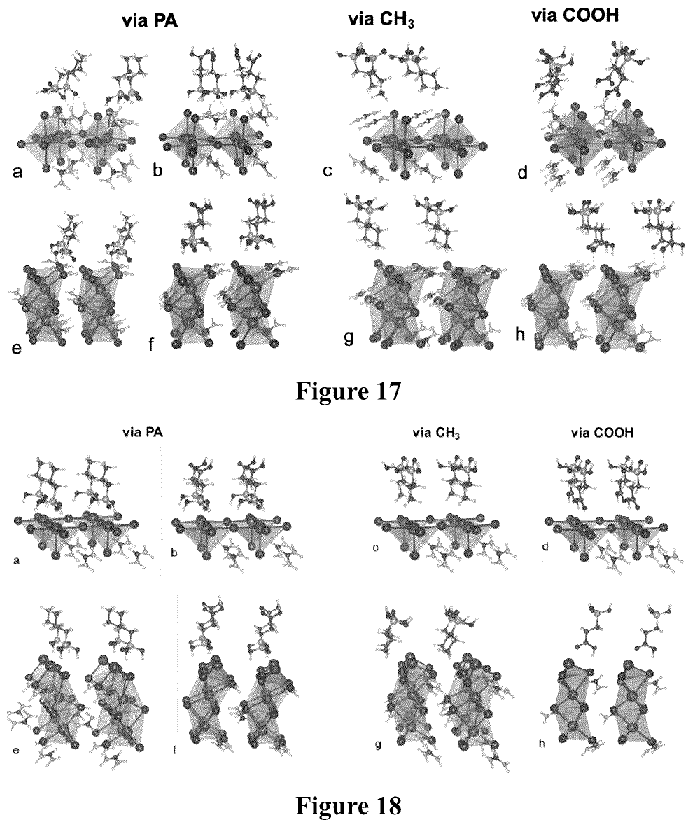

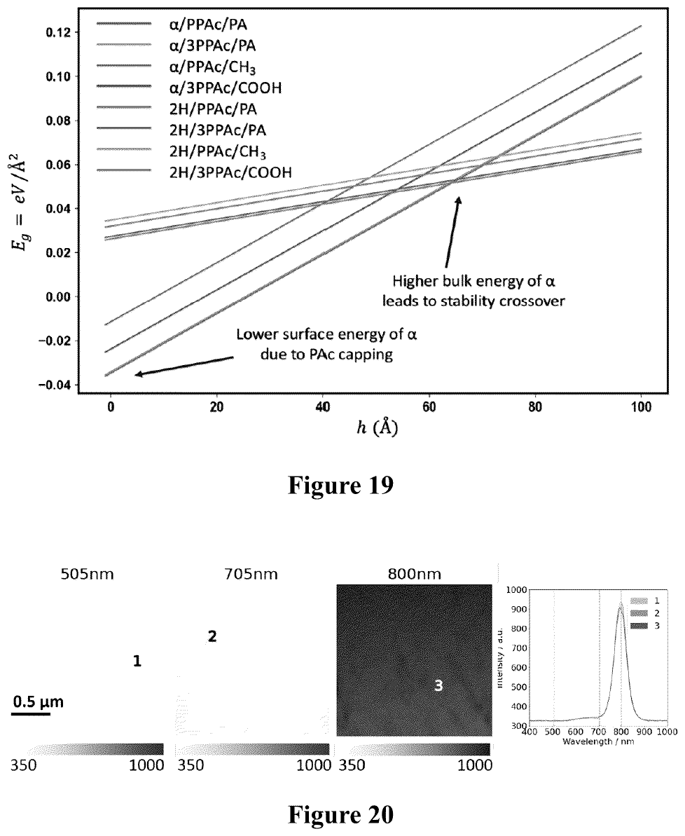

We performed first-principles studies (FIGS. 2C-2G) to shed light on the mechanism by which certain ligands in the PAc molecules promote the growth of α-FAPbI₃, as experimentally observed in FIG. 2B. We modeled the growth of FAPbI₃ on the FTO substrate treated by two different PAc molecules (PPAc and 3PPAc) that exhibited contrasting results in our experiments. As described earlier, we observed, experimentally, the formation of α-FAPbI₃ upon coating the substrate with PPAc, while the 3PPAc treatment formed hexagonal phases. To unravel the underlying mechanisms, we employed quantum mechanical models to simulate the growth of FAPbI₃ slabs interacting with PPAc or 3PPAc. We considered the capping modes involving the phosphonate (PA), methyl (CH₃ group of PPAc), and carboxyl (COOH group of 3PPAc) ligands, on both FAI- and PbI₂-terminated slabs of FAPbI₃ and calculated their corresponding growth energies with DFT. FIGS. 17-19 show all the capping modes and their corresponding growth energies for both the δ- and α-FAPbI₃ phases as a function of the grown thickness. By calculating the energies of capped films of varying thicknesses, we deduced the capping energy (surface energy) and the bulk energy for each PAc and interface type (see Table 1). More specifically, FIG. 2C demonstrates the energetic competition between these phases as a function of modeled layer thickness. The results show that the lowest growth energy is achieved upon capping via the PA group for both PPAc and 3PPAc. This is consistent with the Pb—O distance of 2.4 Å, indicating the formation of covalent bonds for PA-capping modes (of the Pb-terminated slabs) as well as H-bond formation between PAc and terminal FA (of FAI-terminated slabs as shown in FIGS. 2D-2G). Such bond formations result in higher stabilization due to favorable ligand capping, and thus lowering the growth energy. Table 1 summarizes the calculated energetics per Eq. 1-Eq. 3 required to obtain the growth energy per Eq. 4. Most notably, the tabulated data suggest that the capping energies are in general higher (less favorable) for both FAI and PbI₂ terminations of δ and remain generally comparable between the two terminations (FAI and PbI₂) for each phase. To rationalize this key observation, we studied the molecular surface chemistry of both phases before and after PAc molecule capping. As displayed in FIGS. 2D-2G, a denser network of stronger H-bonds between FA ions and terminal iodines is formed in the case of 2H as compared to the α phase (in line with the lower bulk energy of delta-FAPbI₃). This weaker H-bonding within the α-FAPbI₃ phase explains the formation of shorter, stronger hydrogen bonds (H . . . O=1.8 Å) between PAc and terminal FA in the α-(FIG. 2G) in comparison with the 6-FAPbI₃ phase (FIG. 2E) upon capping. Our calculations also showed that capping energies of the COOH mode are lower (more negative) in the FAI termination compared to the PbI₂ termination due to H-bond formation between the carboxylic group of the molecule and the terminal FA (FIGS. 17, d and h). The α phase continues to grow until it reaches a certain thickness where the bulk formation energy contribution becomes large enough to cause a crossover in the growth energy plot (FIG. 2C and FIG. 19). Our model shows that all the interactions of both PPAc and 3PPAc with the FA can help promote the growth of the α-FAPbI₃ phase. However, as reported in Table 1, the energy corresponding to capping via the PA group is significantly more favorable than the CH₃ and COOH modes for both α and δ phases of FAPbI₃. We investigated the effects of structural changes induced by PPAc molecules on the properties and morphology of thin films as shown in FIGS. 3A-3C. FIG. 3A compares the UV-vis absorption spectra of FAPbI₃ films fabricated on bare and PPAc-treated FTO substrates. The films deposited on PPAc-treated substrates exhibit a characteristic absorption edge at around 800 nm, which is close to the absorption edge of the α-FAPbI₃ phase. Likewise, the CL spectra in FIG. 3B and FIG. 20 show narrow peaks centered at around 800 nm and wide peaks centered around 760 nm for the PPAc-treated samples and those deposited on bare FTO, respectively. These results further confirm the formation of the α-FAPbI₃ for the PPAc-treated samples. The PPAc treatment has strong effects on the morphology of the thin films. Scanning electron microscopy (SEM) images show the formation of larger grains for samples prepared on the PPAc-treated substrate when compared to the bare FTO samples, as shown in FIG. 3C, suggesting that PPAc treatment has a strong effect on the sorption of the co-evaporated precursors.

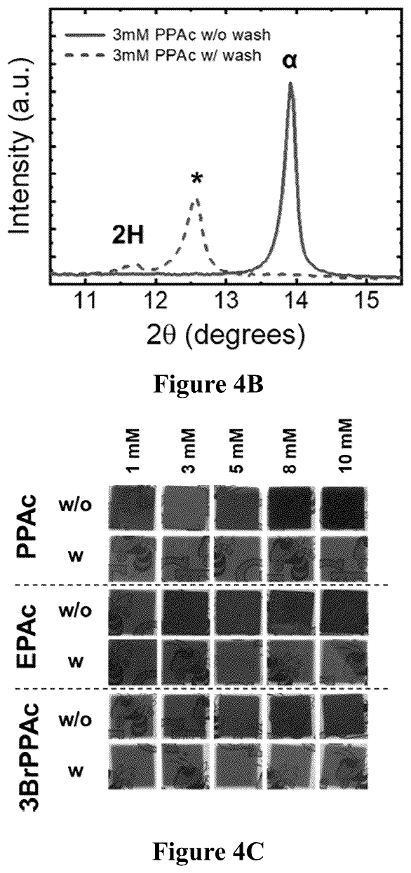

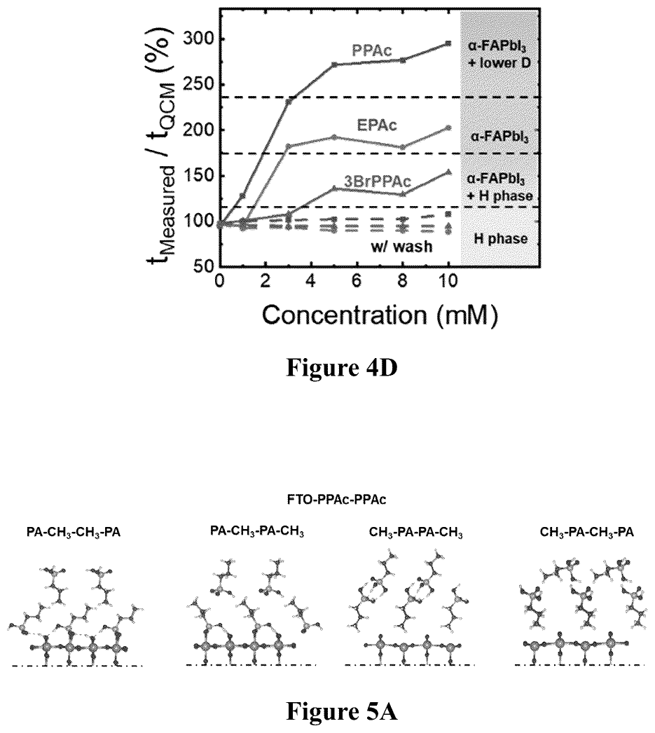

To experimentally separate the effects of the ligand from the PA group, and to unravel the impact of excess phosphonic acid molecules on the formation of the α-FAPbI₃, we removed excess PAc molecules by spin coating ethanol on the treated substrates (hereafter referred to as ethanol wash). This procedure ensures the removal of excess PAc molecules not directly adsorbed to the FTO substrate that could interact with the perovskite layer with random orientations. We believe that this approach maintains close to a single monolayer of molecules, such that the ligand is accessible to the growing FAPbI₃, while the PA group remains buried and bound to the FTO. We measured XPS to confirm the removal of excess PAc molecules from the surface. We used 3BrPPAc as a case study (shown in FIG. 4A) and measured the Br 3d XPS peak area on the substrates treated with varying concentrations of the 3BrPPAc solution, before and after the ethanol wash. The Br 3d peak area increases with concentration in solution of the 3BrPPAc, when no wash is performed. Instead, when the concentration of 3BrPPAc is higher than 5 mM, there is no change in the Br 3d peak area after the ethanol wash, suggesting that PAc concentrations below 5 mM may lead to incomplete coverage of the substrate. In contrast, complete coverage can be achieved at PAc concentrations above 5 mM, with the removal of the unbound (excess) 3BrPPAc during the ethanol wash leaving a monolayer of PAc molecules on the substrate after the wash. In all cases of using ethanol-washed substrates, we observe no evidence of α-FAPbI₃ phase stabilization (FIG. 16). Instead, we grow thin films composed of a mixture of hexagonal phases, nearly identical to the cases with no PAc treatment (FIGS. 4B and 4C). As such, the removal of the excess PAc molecules revealed their key role in the α phase formation. These findings suggest that a single monolayer of PAc molecules is insufficient for the growth of α-FAPbI₃, in agreement with the DFT calculations that predict the α phase formation is most promoted by the PA group capping mode and that the formation of α-FAPbI₃ is contingent upon the excess phosphonic acid molecules.

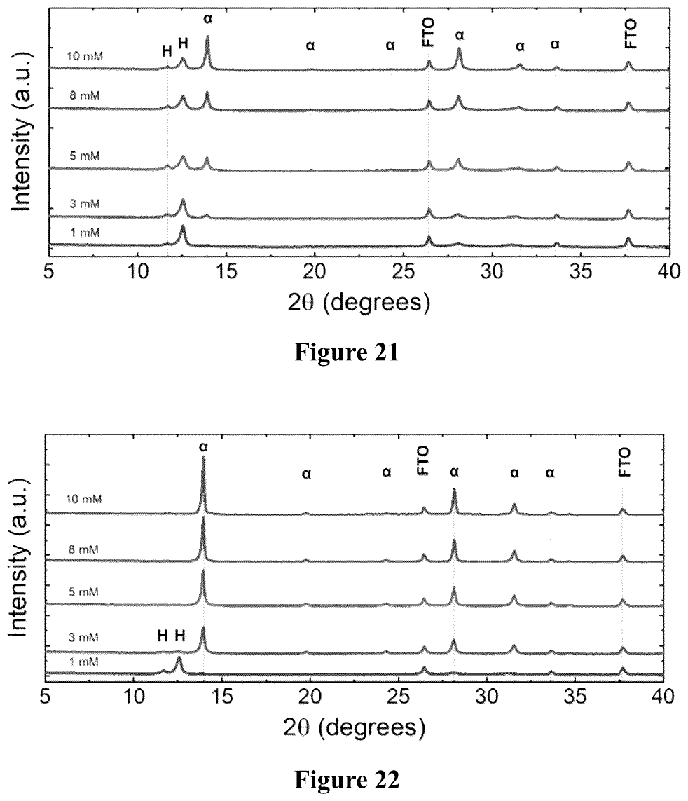

Analogous to the effect of ethanol wash, a solution of PAc molecules at low concentrations also prevents the formation of the α-FAPbI₃ phase. In the photographs shown in FIG. 4C, higher concentrations of PAc molecules lead to thin films with darker color, suggesting the formation of the α-FAPbI₃. This effect can be clearly seen in the films treated with 3BrPPAc (FIG. 21). Substrates treated with a solution of 1 mM of 3BrPPAc show that the film is composed solely of hexagonal phases. However, as the concentration of 3BrPPAc increases, the content of the α phase also increases, achieving an a to hexagonal peak intensity ratio of 2.8:1 at a concentration of 10 mM (FIG. 21). Similar trends are observed for all PAc molecules tested as can be seen in the XRD patterns in FIGS. 21-23. Higher solution concentrations likely provide a larger number of PAc molecules available to interact with the perovskite, promoting the formation and stabilization of the desired α structure. However, slight differences in the phase formation are observed for PAc molecules with different ligands.

In addition to the phase stabilization as a function of PAc molecule type and concentration, we observed that the substrate treatment also affects the thickness of the deposited FAPbI₃ films. FIG. 4D demonstrates the variation in the thickness of FAPbI₃ films deposited on the substrates treated with different PAc molecules and corresponding to different concentrations. In the films deposited on either bare FTO or on substrates washed with ethanol (dominated by δ phases), the thickness of the layer measured by profilometry is the same as that predicted by the QCM near the substrates (QCM1 in FIG. 1A). However, as the content of α-FAPbI₃ increases, the actual thickness of the film also deviates from the thickness predicted by the QCM, almost doubling in value corresponding to pure α-FAPbI₃ film deposition.

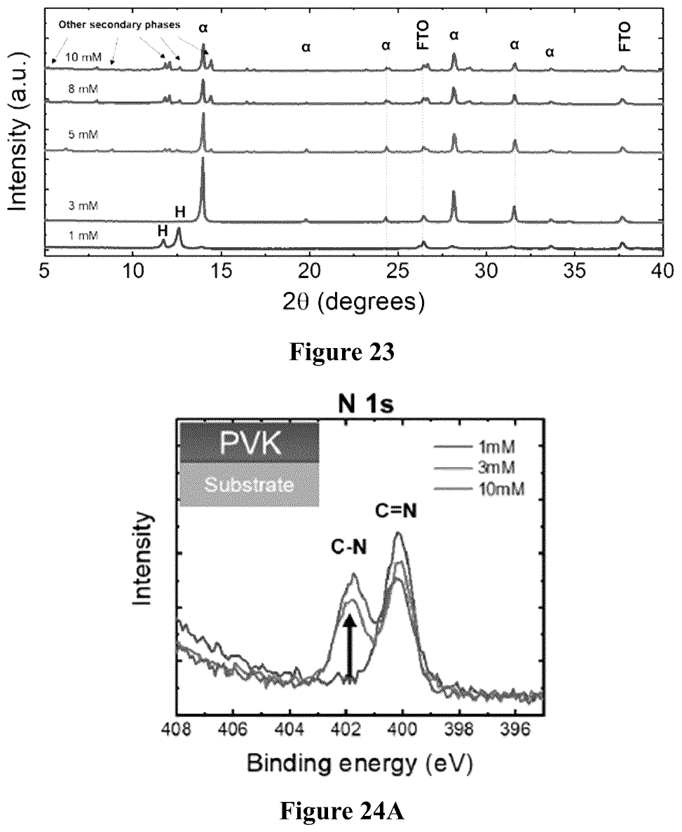

Furthermore, for PPAc treatment at higher concentrations, the XRD exhibits the formation of unknown lower dimensional phases (FIG. 23) accompanied by an increase of three times in the measured thickness of the layer when compared to the predicted by the QCM. It is worth noting that all the samples were deposited on the same evaporation run and that the remarkable change in the thickness cannot be explained solely by the density differences between different crystalline structures. This suggests that the sticking coefficient of the precursor materials is also affected by the PAc molecule treatment, possibly also affecting the layer stoichiometry.

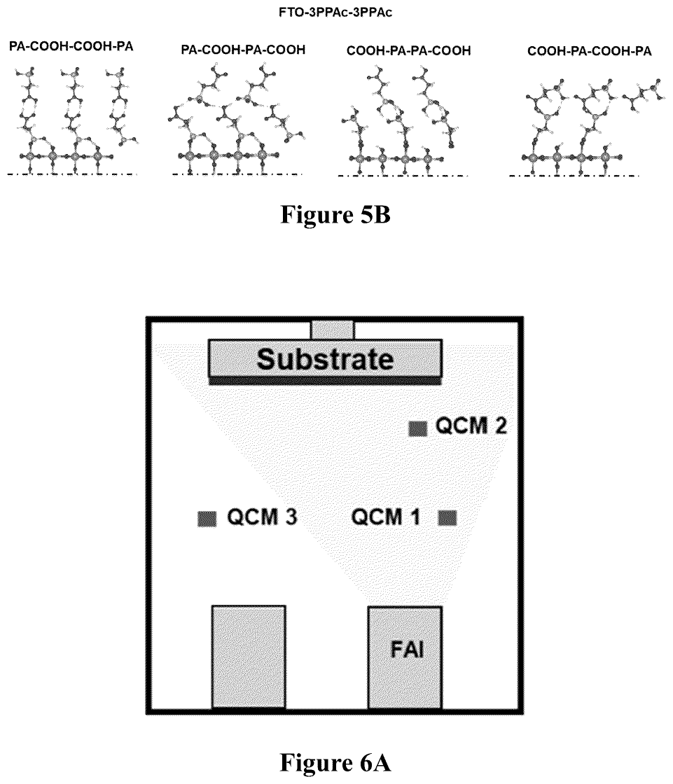

TABLE 2
BEs of the Upper-Layer PAc Molecule to the FTO-Bound Monolayer Corresponding
to Various Intermolecular Binding Modes. BEs were calculated according
to Eq. 5, and the definitions of different substrate-PAc and PAc-PAc
binding modes are given in the caption of FIGS. 5A-5B.

| binding | PA—CH₃— | PA—CH₃— | CH₃—PA— | CH₃—PA— |
|---|---|---|---|---|
| mode | CH₃—PA | PA—CH₃ | PA—CH₃ | CH₃—PA |
| BE (eV) | −0.34 | −0.53 | −1.60 | −1.40 |

| binding | PA—COOH— | PA—COOH— | COOH—PA— | COOH—PA— |
|---|---|---|---|---|
| mode | COOH—PA | PA—COOH | PA—COOH | COOH—PA |
| BE (eV) | −1.02 | −1.03 | −2.70 | −2.92 |

Analyzing the above results points to important aspects of the growth mechanism, offering connections between our experimental and theoretical results. The experiments discussed in FIGS. 4A-4D show that the mere presence of the monolayer passivating the substrate is insufficient to form α-FAPbI₃. The data also confirm that having an excess of PPAc is essential for the formation of the α-FAPbI₃ phase. However, it is observed that an excess of 3PPAc molecules leads exclusively to the formation of hexagonal FAPbI₃ phases. These results suggest that the ligand (propyl vs. carboxylic groups) also plays an important role in the α-FAPbI₃ formation. Thus, we performed DFT calculations and studied ligand-ligand interactions to understand the role of the ligand on their migration during perovskite deposition. Here, we considered a bilayer arrangements of PPAc and 3PPAc molecules. Our models, depicted in FIGS. 5A-5B, encompass all the major modes of binding for which we calculated the BE according to Eq. 6 and reported in Table 2. We show the formation of H-bond pairs between the carboxyl groups of the top and bottom layers in the PA-COOH—COOH-PA configuration. We also observed a chain of H-bonds between the carboxyl and the PA groups of the top and bottom layers in the PA-COOH-PA-COOH ligand-ligand binding mode. These results are consistent with the large ligand-ligand BEs reported in Table 2. Conversely, for PPAc and its favorable mode of binding to the substrate (via PA), a weak interaction (˜0.34 eV) between the top- and bottom-layer methyl groups was calculated (Table 2). These findings emphasize the significance of the ligand in PAc molecules, explaining why molecules with aliphatic moieties such as PPAc and EPAc are more effective in promoting the growth of α-FAPbI₃, as their weaker ligand-ligand interactions can facilitate their migration to the top of the film during growth.

### Phosphonic Acid Migration and the Sorption Rate of FAI.

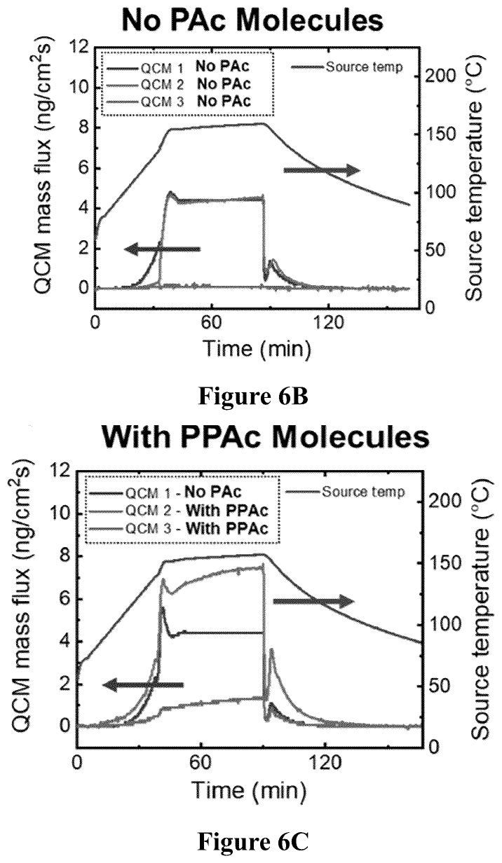

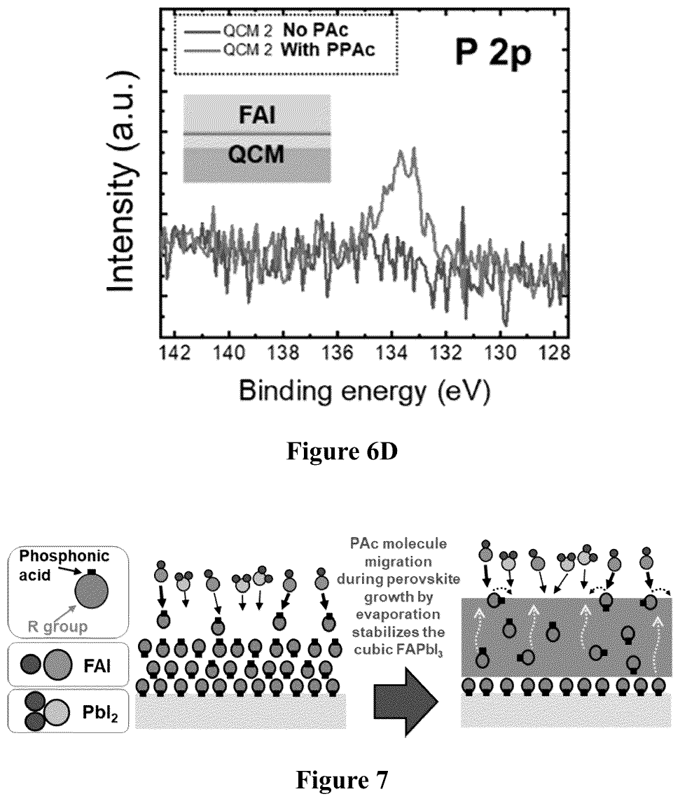

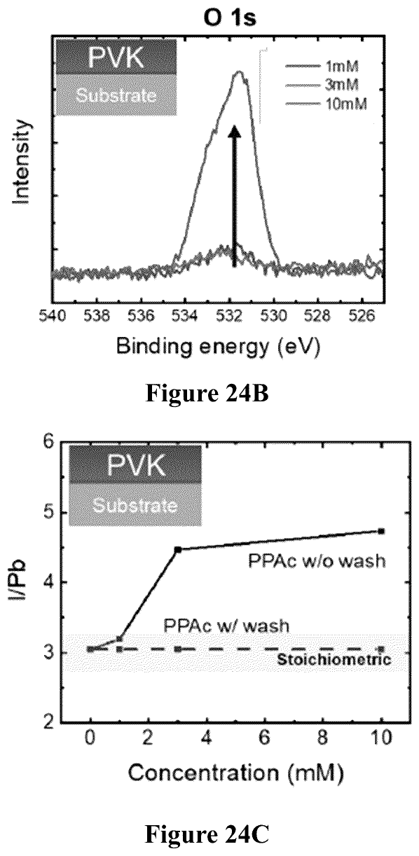

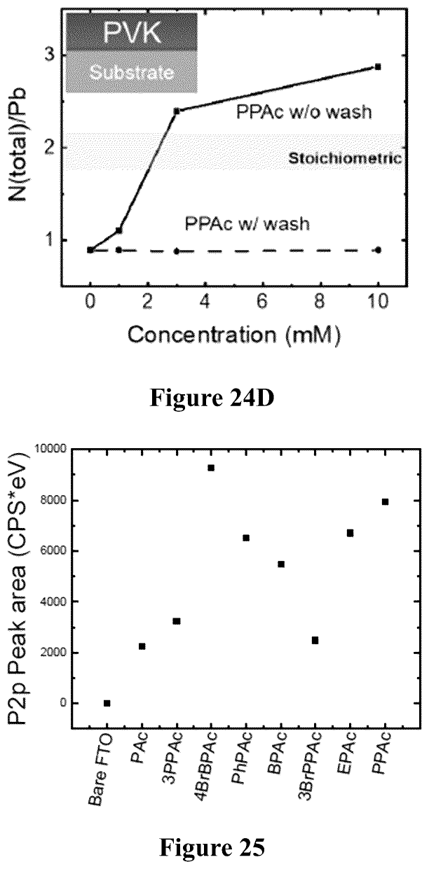

To understand the effect of PAc molecules on FAI adsorption, we evaporated FAI thin films without the PbI₂ (FIG. 6A). The evaporation rate was kept constant between experiments by using a QCM without treatment near the FAI source, as shown in FIG. 6B. We observe that treatment with the 3 mM PPAc (QCM 2) caused an increase in the mass flux of more than 50% with respect to the bare QCM 1 (FIG. 6C). Furthermore, the treated QCM outside of the evaporation cone (QCM 3) also registered a significant mass flux, which might be related to the sorption of FAI itself or byproducts of the evaporated FAI. These findings confirm that the presence of excess PPAc molecules leads to increased FAI sorption, which, in turn, will affect the stoichiometry of the perovskite films. It is important to note that the increase in mass flux from FAI evaporation detected with the treated QCM not only occurs at the beginning of the evaporation but continues throughout the entire process. XPS analysis of the 200 nm FAI film on treated QCMs is shown in FIG. 6D and an extended discussion of the perovskite stoichiometry deposited on treated and bare FTO substrates can be found in FIGS. 24A-24D. The surface chemistry analysis revealed the presence of phosphorus (P 2p) on the surface of the FAI films. This may explain why we see increased sorption of FAI in the presence of PPAc treatment as the PPAc molecules appear to be migrating as we deposit FAI. This migration can be rationalized through the discussion in FIGS. 5A-5B and Table 2, where we calculate weaker interactions between the ligands in PPAc. FIG. 25 shows a comparison of the XPS P 2p signal for FAI films evaporated on gold-plated silicon substrates treated with different PAc molecules. The PAc molecules that are less effective in fostering the α-FAPbI₃ growth also exhibited a lower intensity of the P 2p signal coming from the surface of the FAI layer. These findings suggest that the ligands of PPAc influence the migration of the molecules toward the surface. In turn, the FAI absorption efficiency may lead to the formation of stoichiometric perovskites and α-FAPbI₃, which explains the increased N/Pb ratio observed in the XPS measurements (FIGS. 24A-24D). Moreover, it explains why performing an ethanol wash of the treated substrate (which removes excess ligands) results in obtaining only hexagonal phases.

### Proposed Mechanism for the Formation of α-FAPbI₃.

We propose a mechanism of α-FAPbI₃ growth on the substrates treated with PPAc molecules as shown in FIG. 7. First, the treatment with the PAc solution enables the adsorption of phosphonic acids onto the FTO and formation of P—O covalent bonds that results in the formation of a PPAc monolayer on the substrate. Excess PPAc molecules that exhibit weak interligand (e.g., propyl) interactions are able to migrate away from the substrate and interact with the PbI₂ and FAI, where the phosphonic acid enables the stabilization of α-FAPbI₃ during growth. This continued process increases the FAI sorption rate and enables the formation of the α-FAPbI₃ through the decrease of the α phase growth energy, thus making it the favored phase to grow.

Stability under Nitrogen and Humid Air.

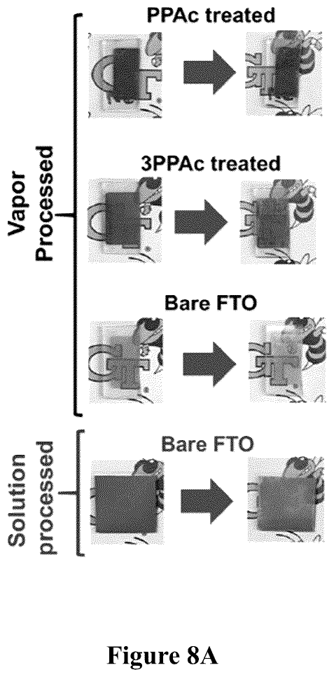

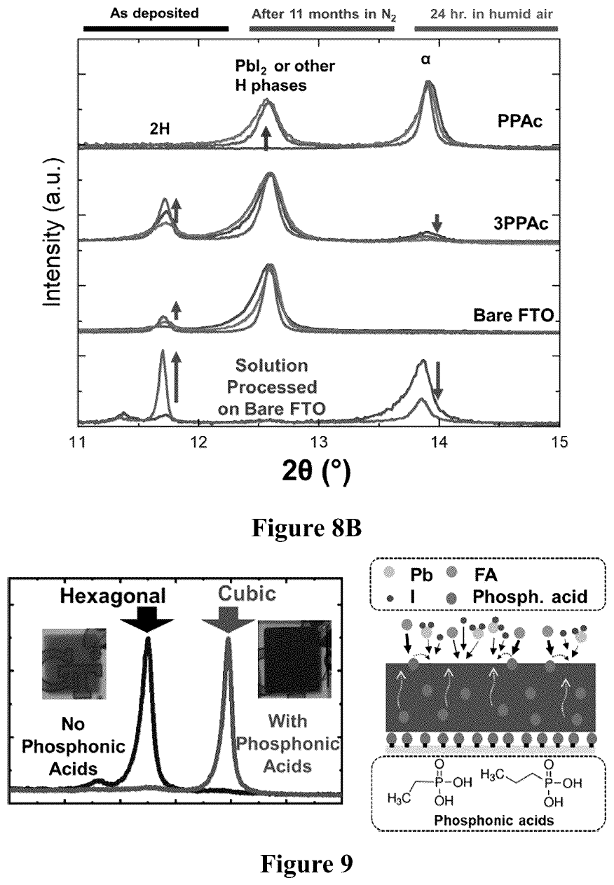

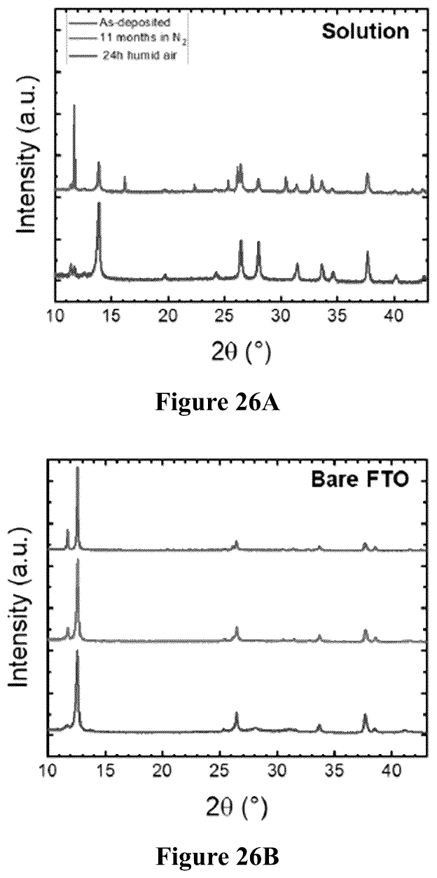

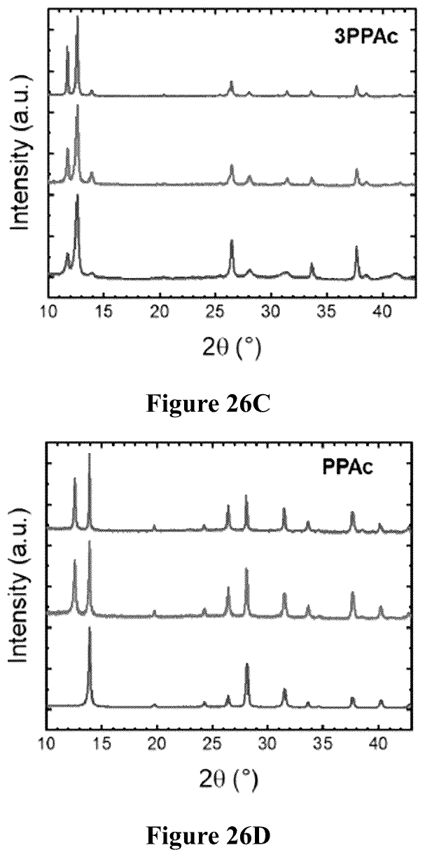

We measured the stability of the FAPbI₃ films deposited via evaporation with and without PAc molecules and compared them with films deposited via spin-coating, as the α-FAPbI₃ phase undergoes phase transformations in the presence of oxygen and moisture. The photographs of the films show visual degradation after exposure to moist air over 24 h (FIG. 8A), for all samples except the PPAc-treated materials. The PPAc-treated materials retain a significant amount of α-FAPbI₃ even after an extended storage period of 11 months in a nitrogen glovebox (FIG. 8B). The XRD analysis reveals the formation of some amount of PbI₂ or 4H/6H hexagonal phases for the PPAc thin films, without any 2H-FAPbI₃ formation. The films deposited on bare FTO and 3PPAc exhibit peaks that belong to the 2H-FAPbI₃ and PbI₂ or 4H/6H hexagonal phases. FIGS. 26A-26D present the complete XRD patterns. Importantly, exposure to humid air (˜80% relative humidity) for 24 h presents no major changes in the crystalline structure of the PPAc-treated samples. In contrast, solution-processed FAPbI₃ films experience rapid degradation in the presence of moisture, with 2H-FAPbI₃ becoming the predominant phase after 24 h. These results show that the presence of PPAc in the film not only promotes the growth of α-FAPbI₃ but also prevents the phase transformation of α-FAPbI₃ to the 2H phase.

### CONCLUSION

Substrate treatment with PAc molecules was successfully implemented to induce the growth of metal halide cubic perovskites, the α-FAPI₃ phase, by thermal evaporation at room temperature. We investigated the role of substrate treatment on the phase purity and composition of the perovskite layer. The presence of the PAc group in the molecules was found to be most effective in promoting the α-FAPI₃ phase formation by decreasing the growth energy associated with it to the greatest extent, as demonstrated by our DFT calculations. Notably, our findings revealed that the primary mechanism of driving the α-FAPI₃ phase growth extends beyond the buried substrate-ligand interface. It is evident that unbound excess ligands play a crucial role in the α-FAPI₃ phase growth by migrating toward the surface and enhancing the sorption rate of the organic perovskite precursor onto the substrate. This is supported by our XPS analysis and intermolecular BE calculations explaining the inability of PAc molecules with higher ligand-ligand BEs to promote the α phase growth. In addition, the PPAc-treated samples maintained the α-FAPI₃ phase after 24 h of exposure to moist air. This Example underscores the importance of surface treatment through PAc molecular design to facilitate the α-FAPI₃ phase growth for next-generation photovoltaic and light emitting devices.

### Materials and Methods

### Substrate Cleaning.

The FTO substrates underwent a cleaning procedure involving sequential sonication for 15 min each in 2% mucasol (Schülke) solution, distilled water, acetone (Sigma-Aldrich, ≥99.5%), and isopropyl alcohol (Fischer Chemical). Subsequently, the substrates were dried using a nitrogen gun. Prior to the phosphonic acid treatment step, the substrates were exposed to a UV-ozone cleaner for 15 min.

### Phosphonic Acid Treatment.

A solution of the phosphonic acid in ethanol (Sigma-Aldrich, 99%) was prepared and stirred for 1 h in a vortex mixer inside the glovebox. The concentration of the PAc solution varied from 1 to 10 mM. Subsequently, 100 μL of solution was dispensed onto the substrate and evenly spread. After allowing 1 min for settling, the spin-coating process was initiated, using a speed of 3000 rpm for 30 s with 1000 rpm/s of acceleration. Following the spin-coating step, the sample underwent annealing at 100° C. for 10 min.

### FAPbI₃ Evaporation.

Thermal evaporation was conducted using a Kurt J. Lesker MiniSpectros series low-temperature evaporator. Prior to deposition, the PbI₂ and FAI deposition rates were accurately calibrated using dedicated QCMs positioned near the respective sources. The final thickness of the deposited materials on the substrate was continually monitored using another QCM placed near the substrate holder. During the evaporation process, the deposition rate of PbI₂ was maintained at 0.4 X/s, while the deposition rate of FAI was set to 0.44 Å/s. Typically, the evaporation was terminated when achieving a total thickness of around 400 nm on the substrates. To enhance film uniformity, the samples were rotated at a speed of 10 rpm throughout the evaporation procedure.

### Computational Methods.

Bare and PAc-passivated stoichiometric slabs (with either PbI₂ or FAI terminated surfaces) of α- and δ(2H)-FAPbI₃ were constructed from 2×2×4 and 1×1×3 supercells of their corresponding conventional unit cells, composed of 192 and 72 atoms, respectively (See FIGS. 17 and 18 where only the top few layers of reconstructed FAI- and PbI₂-terminated slabs are shown, for clarity). DFT calculations with the Perdew-Burke-Ernzerhof exchange-correlation functional revised for solids and surfaces (revPBE) were performed using the Quantum Espresso suite of codes. Ultrasoft pseudopotentials were used to describe the interaction between the valence electrons and the ionic cores. Kohn-Sham orbitals were expanded in a plane-wave basis set with a kinetic energy cutoff of 60 Ry and a density cutoff of 420 Ry. van der Waals interactions were incorporated via the empirical D3 dispersion correction scheme. E_{form} of bulk FAPbI₃ in δ and α phases were calculated based on the reaction FAI+PbI₂→FAPbI₃, per Eq. 1, where E_{FAP1}, E_{PbI2}, and E_{FAI} represent the DFT energies FAPbI₃ and the precursors (PbI₂ and FAI). The growth energy (E_{g}, Eq. 4) defined as the summation of (a) the formation energy of the unit volume of FAPI (E_{form}, Eq. 1) multiplied by the thickness (h), (b) the separation energy (Eₛₑₚ, Eq. 2), which is the energy required to cleave the slab from the bulk, and (c) the slab-ligand capping energy (E_{cap}, Eq. 3) gained due to capping the slab with ligands, was computed for each passivated slab. In this formulation, Eₛₑₚ is the energy required to form the unit area of the slab from the bulk phase, E_{slab} and E_{bulk} are total energies of the slab and the bulk phase, and A is the surface area of the slab. The capping energy (E_{cap}) is also obtained from the total energies of the bare (E_{slab}) and ligand-capped slabs (E_{slab-PAc}). Furthermore, to study the FTO-treatment via PAc ligands, we constructed stoichiometric slab models of undoped SnO₂ (110), which is thermodynamically most stable and will refer to it as FTO for consistency. FTO-PAc BEs were calculated from the DFT energies of the bare (E_{FTO}) and PAc-capped (E_{FTO-PAc}) slabs according to Eq. 5. To assess the ligand-ligand bond dissociation during the evaporative deposition of FAPbI₃, we computed the ligand-ligand BE (BE_{PAc-PAc}) per Eq. 6, from the total energies of the bilayer- and monolayer-treated FTO (E_{(FTO-PAc-PAc)} and E_{(FTO-PAc)}) and the upper-layer ligand (E_{PAc}).

### Characterization.

XPS was conducted with a Thermo Scientific K-Alpha system using a monochromatic Al Kα X-ray source (1486.6 eV) with a 600 incident angle and a 0° photoemission angle, both measured from the sample normal. Survey and high-resolution scans were collected. High-resolution scans were taken with a 0.100 eV step size for P 2p, C 1s, N 1s, 13d, O 1s, Pb 4f, and Br 3d. XRD measurements were done in a third-generation Panalytical Empyrean diffractometer. GIWAXS was performed at the beamline 11-BM at the National Synchrotron Light Source II in Brookhaven National Laboratory. The samples were measured with incidence angles between 0.1 and 0.5° with a 20 s exposure time, using a beam with an energy of 13.5 keV, 0.2 mm×0.05 mm size, 1 mrad divergence, and an energy resolution of 0.7%. UV-vis absorption spectra were taken with a Cary 5000 UV-vis/NIR spectrometer. The thickness of the films was measured with a Bruker Dektak XT profilometer. CL spectra were taken at the Center for Nanophase Materials Science at Oak Ridge National Laboratory with a FEI Quattro environmental SEM and Delmic Sparc CL collection module. Electron beam energy was 5 keV and current was 7 pA. CL signal acquisition time was 100 ms with a pixel size of 40 nm. The data were processed using python libraries developed by Sergei Kalinin and Jonghee Yang.

### Surface Chemistry Discussion of FAPbI₃ and FAI Films Deposited on Surface Treated and Bare FTO.

To further understand the proposed mechanism of PPAc molecules migrating during thin film growth, we studied the surface chemistry of perovskite films grown on treated samples and bare substrates. In general, having a ratio of less than 3:1 for iodine:lead, and less than 1:1 for the organic:lead (often obtained from the nitrogen signal in XPS) is an indication of forming non-perovskite phases. In FIGS. 24A-24D, we present the ratio of I:Pb and N:Pb as a function of PAc concentration, using PPAc as an example, as it is the most effective molecule driving the conversion of the deposited FAPbI₃ film to the α phase. A stoichiometric α-FAPbI₃ is expected to have an I:Pb ratio of 3:1 and an N:Pb ratio of 2:1. The XPS data of films deposited on bare FTO reveals an I:Pb ratio around 3:1, as expected in a FAPbI₃ film, but a N:Pb ratio of about 0.9:1. This finding suggests that the films deposited on bare FTO have a deficiency of FA+cations. We speculate that this deficiency contributes to the formation of the observed hexagonal phases. This is in addition to our findings that without capping FAPbI₃ with phosphonic acids the growth energy of the 8-FAPbI₃ is more favorable than that of the α-FAPbI₃ (Table 1). On the other hand, as the concentration of PPAc increases, the ratio of N:Pb also increases, achieving a value close to 2 in films where only the α phase can be observed in the diffraction pattern. For concentrations above 5 mM of the PPAc molecule, we found ratios above 2:1 of N:Pb. This high level of organic cations correlates with the emergence of lower dimensional phases in the film observed in XRD (FIG. 23). Moreover, the O is XPS signal increases as we increase the PPAc concentration (FIGS. 24A-24D), suggesting the adsorption of oxygen species as more FA, which is hygroscopic, is incorporated in the film. It is possible that this signal belongs to the oxygen species in the PAc molecules. In addition, we expect the excess of organics in FAPbI₃ films to induce the formation of low dimensional phases, analogously to what is observed in thermally evaporated MAPbI₃ perovskites. Conversely, we observed no change in the I:Pb or N:Pb ratios of measured XPS for FAPbI₃ films deposited on the washed substrates, suggesting that a monolayer of PPAc is not enough to drive sufficient adsorption of FA molecules.

In addition to the FAI C═N bond peak signal (at 400 eV), the XPS N is scan shows the presence of a C—N bond peak (at 401.85 eV, FIG. 24A) in the films on substrates that are functionalized with PAc molecules. It is possible that this signal belongs to FAI byproducts with C—N bond characteristics and that are incorporated in the perovskite structure during deposition. However, no clear structural effects were shown as this XPS peak increases in intensity

TABLE 3
The energy corresponding to the first ligand binding
the FTO surface, at PBEsol + D3 level of theory, for
PA, CH₃ (of PPA) and COOH (of 3PPAc) binding modes.

| mode | |
|---|---|
| PA | CH₃ (or COOH) |

| PAc | PPAc | 3PPAc | PPAc | SPPAc |
|---|---|---|---|---|
| BE_{PAc} (eV) | −4.11 | −3.99 | −0.6 | −1.51 |

### REFERENCES

(1) Kojima, A.; et al. Organometal Halide Perovskites as Visible-Light Sensitizers for Photovoltaic Cells. J. Am. Chem. Soc. 2009, 131 (17), 6050-6051.
(2) Yoo, J. J.; et al. Efficient Perovskite Solar Cells via Improved Carrier Management. Nature 2021, 590 (7847), 587-593.
(3) Min, H.; et al. Perovskite Solar Cells with Atomically Coherent Interlayers on SnO₂ Electrodes. Nature 2021, 598 (7881), 444-450.
(4) Wang, J.; et al. Advancing Vapor-Deposited Perovskite Solar Cells via Machine Learning. J. Mater. Chem. A 2023, 11 (25), 13201-13208.
(5) Lee, J. H.; et al. Opportunities and Challenges for Perovskite Solar Cells Based on Vacuum Thermal Evaporation. Adv. Mater. Technol. 2023, 8, 2200928.
(6) Zhou, Y; et al. Effect of Solvent Residue in the Thin-Film Fabrication on Perovskite Solar Cell Performance. ACS Appl. Mater. Interfaces 2022, 14 (25), 28729-28737.
(7) Kim, B. S.; et al. Deposition Kinetics and Compositional Control of Vacuum-Processed CH₃NH₃PbI₃ Perovskite. J. Phys. Chem. Lett. 2020, 11 (16), 6852-6859.
(8) Borchert, J.; et al. Impurity Tracking Enables Enhanced Control and Reproducibility of Hybrid Perovskite Vapor Deposition. ACS Appl. Mater. Interfaces 2019, 11 (32), 28851-28857.
(9) Wang, K.; et al. Evaporation of Methylammonium Iodide in Thermal Deposition of Mapbi3. Nanomaterials 2021, 11 (10), 2532.
(10) Kroll, M.; et al. Insights into the Evaporation Behavior of FAI: Material Degradation and Consequences for Perovskite Solar Cells. Sustainable Energy Fuels 2022, 6 (13), 3230-3239.
(11) Castro-Mendez, A. F.; et al. Formation of a Secondary Phase in Thermally Evaporated MAPbI₃ and Its Effects on Solar Cell Performance. ACS Appl. Mater. Interfaces 2022, 14 (30), 34269-34280.
(12) Juarez-Perez, E. J.; et al. Thermal Degradation of Formamidinium Based Lead Halide Perovskites into Sym-Triazine and Hydrogen Cyanide Observed by Coupled Thermogravimetry-Mass Spectrometry Analysis. J. Mater. Chem. A 2019, 7 (28), 16912-16919.
(13) Correa-Baena, J.-P.; et al. The Rapid Evolution of Highly Efficient Perovskite Solar Cells. Energy Environ. Sci. 2017, 10, 710-727.
(14) Correa-Baena, J. P.; et al. Promises and Challenges of Perovskite Solar Cells. Science 2017, 358 (6364), 739-744.
(15) Gratia, P.; et al. The Many Faces of Mixed Ion Perovskites: Unraveling and Understanding the Crystallization Process. ACS Energy Lett. 2017, 2 (12), 2686-2693.
(16) Beckmann, P. A Review of Polytypism in Lead Iodide. Cryst. Res. Technol. 2010, 45 (5), 455-460.
(17) An, Y; et al. Identifying High-Performance and Durable Methylammonium-Free Lead Halide Perovskites via High-Throughput Synthesis and Characterization. Energy Environ. Sci. 2021, 14 (12), 6638-6654.
(18) An, Y; et al. Structural Stability of Formamidinium- And Cesium-Based Halide Perovskites. ACS Energy Lett. 2021, 6 (5), 1942-1969.
(19) Cordero, F.; et al. Stability of Cubic FAPbI₃ from X-Ray Diffraction, Anelastic, and Dielectric Measurements. J. Phys. Chem. Lett. 2019, 10 (10), 2463-2469.
(20) Jesper Jacobsson, T.; et al. Exploration of the Compositional Space for Mixed Lead Halogen Perovskites for High Efficiency Solar Cells. Energy Environ. Sci. 2016, 9 (5), 1706-1724.
(21) Saidaminov, M. I.; et al. Suppression of Atomic Vacancies via Incorporation of Isovalent Small Ions to Increase the Stability of Halide Perovskite Solar Cells in Ambient Air. Nat. Energy 2018, 3 (8), 648-654.
(22) Kim, H. S.; et al. Importance of Tailoring Lattice Strain in Halide Perovskite Crystals. NPG Asia Mater. 2020, 12, 78.
(23) Jones, T. W.; et al. Lattice Strain Causes Non-Radiative Losses in Halide Perovskites. Energy Environ. Sci. 2019, 12 (2), 596-606.
(24) Jin, B.; et al. Strain Relaxation for Perovskite Lattice Reconfiguration. Adv. Energy Sustainability Res. 2023, 4, 2200143.
(25) Conings, B.; et al. Intrinsic Thermal Instability of Methylammonium Lead Trihalide Perovskite. Adv. Energy Mater. 2015, 5 (15), 1500477.
(26) Egger, D. A.; et al. Theory of Hydrogen Migration in Organic-Inorganic Halide Perovskites. Angew. Chem., Int. Ed. 2015, 54 (42), 12437-12441.
(27) Liu, L.; et al. A-Site Phase Segregation in Mixed Cation Perovskite. Mater. Rep.: Energy 2021, 1 (4), 100064.
(28) Olthof, S.; et al. Substrate-Dependent Electronic Structure and Film Formation of MAPbI₃ Perovskites. Sci. Rep. 2017, 7 (1), 40267.
(29) Roβ, M.; et al. Co-Evaporated Formamidinium Lead Iodide Based Perovskites with 1000 h Constant Stability for Fully Textured Monolithic Perovskite/Silicon Tandem Solar Cells. Adv. Energy Mater. 2021, 11 (35), 2101460.
(30) Feeney, T.; et al. Understanding and Exploiting Interfacial Interactions between Phosphonic Acid Functional Groups and Co-Evaporated Perovskites. Matter 2024, 7, 2066-2090.
(31) Weber, O. J.; et al. Phase Behavior and Composition in the Formamidinium-Methylammonium Hybrid Lead Iodide Perovskite Solid Solution. J. Mater. Chem. A 2016, 4 (40), 15375-15382.
(32) Yang, J.; et al. Understanding the Role of Cesium on Chemical Complexity in Methylammonium-Free Metal Halide Perovskites. Adv. Energy Mater. 2023, 13 (33), 2202880.
(33) Woo, Y W.; et al. Inhomogeneous Defect Distribution in Mixed-Polytype Metal Halide Perovskites. ACS Energy Lett. 2023, 8 (1), 356-360.
(34) Rao, M.; et al. Band Gap Determination in Lead Iodide Polytypes. Solid State Commun. 1980, 35 (10), 801-804.
(35) Lin, D.; et al. Vapor Deposited Pure α-FAPbI₃ Perovskite Solar Cell via Moisture-Induced Phase Transition Strategy. Adv. Funct. Mater. 2022, 32 (48), 2208392.
(36) Li, N.; et al. Enhanced Moisture Stability of Cesium-Containing Compositional Perovskites by a Feasible Interfacial Engineering. Adv. Mater. Interfaces 2017, 4 (20), 1700598.
(37) Hidalgo, J.; et al. Synergistic Role of Water and Oxygen Leads to Degradation in Formamidinium-Based Halide Perovskites. J. Am. Chem. Soc. 2023, 145, 24549-24557.
(38) Hidalgo, J.; et al. Bulky Cation Hinders Undesired Secondary Phases in FAPbI₃ Perovskite Solar Cells. Mater. Today 2023, 68, 13-21.
(39) Perdew, J. P.; et al. Restoring the Density-Gradient Expansion for Exchange in Solids and Surfaces. Phys. Rev. Lett. 2008, 100 (13), 136406.
(40) Giannozzi, P.; et al. QUANTUM ESPRESSO: AModular and Open-Source Software Project for Quantum Simulations of Materials. J. Phys.: Condens. Matter 2009, 21, 395502.
(41) Grimme, S. Semiempirical GGA-Type Density Functional Constructed with a Long-Range Dispersion Correction. J. Comput. Chem. 2006, 27 (15), 1787-1799.

The compositions and methods of the appended claims are not limited in scope by the specific compositions and methods described herein, which are intended as illustrations of a few aspects of the claims and any compositions and methods that are functionally equivalent are intended to fall within the scope of the claims. Various modifications of the compositions and methods in addition to those shown and described herein are intended to fall within the scope of the appended claims. Further, while only certain representative materials and method steps disclosed herein are specifically described, other combinations of the materials and method steps also are intended to fall within the scope of the appended claims, even if not specifically recited. Thus, a combination of steps, elements, components, or constituents may be explicitly mentioned herein; however, other combinations of steps, elements, components, and constituents are included, even though not explicitly stated.

What is claimed is:

1. A method comprising:
depositing a layer comprising one or more phosphonic acids on a substrate to form a functionalization layer disposed on the substrate; and
evaporating one or more precursor materials on the functionalization layer to form an active layer comprising a semiconducting perovskite material disposed on the functionalized layer.

2. The method of claim 1, wherein the functionalization later has a thickness greater than a monolayer.

3. The method of claim 2, wherein the functionalization layer has a thickness of from 1 nm to 250 nm.

4. The method of claim 1, wherein depositing the layer comprising one or more phosphonic acids on the substrate comprises spin coating the one or more phosphonic acids, dip coating one or more phosphonic acids, spray coating one or more phosphonic acids, ink jet printing one or more phosphonic acids, or a combination thereof.

5. The method of claim 1, wherein the one or more phosphonic acids comprise a phosphonic acid defined by the formula below
R—PO—(OH)₂
where R represents a C₁-C₈ alkyl group.

6. The method of claim 5, wherein the one or more phosphonic acids comprise methyl phosphonic acid, propylphosphonic acid (PPAc), isopropylphosphonic acid, ethylphosphonic acid (EPAc), butyl phosphonic acid, tert-butyl phosphonic acid, pentyl phosphonic acid, hexyl phosphonic acid, or a combination thereof.

7. The method of claim 1, wherein the one or more precursor materials comprises an organic component and an inorganic component.

8. The method of claim 7, wherein the organic component comprises an organic monovalent defined by the formula [R¹R²N CH═NR³R⁴]⁺: 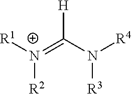
wherein each of R¹, R², R³ and R⁴ may be the same or different and is selected from hydrogen, an unsubstituted or substituted C₁-C₂₀ alkyl group and an unsubstituted or substituted C₅-C₁₈ aryl group.

9. The method of claim 7, wherein the organic component comprises a formamidinium salt, such as formamidinium iodide, or a methylammonium salt, such as methylammonium iodide.

10. The method of claim 7, wherein the inorganic component comprises Pb, Sn, Ge, Si, Ti, Bi, In, or a combination thereof.

11. The method of claim 10, wherein the inorganic component comprises a lead halide, such as PbI₂.

12. The method of claim 7, wherein evaporating one or more precursor materials on the functionalization layer comprises simultaneous vapor phase deposition of the organic component and the inorganic component.

13. The method of claim 12, wherein the organic component and the inorganic component are each deposited at a deposition rate of from 0.2 Å/second to 0.8 Å/second.

14. The method of claim 1, wherein evaporation is continued until the active layer has a thickness of from 100 nm to 100 m.

15. The method of claim 1, wherein the semiconducting perovskite material exhibits a substantially cubic phase.

16. The method of claim 1, wherein the semiconducting perovskite material is substantially free of a δ-phase.

17. The method of claim 1, further comprising rotating the substrate during evaporation of the one or more precursor materials on the functionalization layer to enhance uniformity of the active layer.

18. The method of claim 1, further comprising coating the substrate with an electron transport layer (ETL) or a hole transport layer (HTL) prior to depositing the layer comprising the one or more phosphonic acids on the substrate.

19. The method of claim 18, wherein the method further comprises coating the substrate with the ETL, wherein the ETL comprises tin oxide, titanium oxide, zinc oxide, a fullerene-based material, or a combination thereof; or
wherein the method further comprises coating the substrate with the HTL, and the HTL comprises nickel oxide, vanadium oxide, spiro OMeTAD, poly[bis(4-phenyl)(2,4,6-trimethylphenyl)amine (PTAA), phosphonic acid based molecules such as ([2-(9H-carbazol-9-yl)ethyl]phosphonic acid (2PACz), or a combination thereof.

20. A composition comprising:
a substrate;
a functionalization layer disposed on the substrate, wherein the functionalization layer comprises one or more phosphonic acids; and
an active layer comprising a semiconducting perovskite material disposed on the functionalized layer.
